(19) United States
(12) Patent Application Publication
(10) Pub. No.: US 2026/0082611 A1
(43) Pub. Date: Mar. 19, 2026

(54) NITRIDE SEMICONDUCTOR DEVICE

(71) Applicant: Panasonic Holdings Corporation, Osaka (JP)

(72) Inventors: Naohiro TSURUMI, Kyoto (JP); Satoshi TAMURA, Osaka (JP); Naoki TORII, Osaka (JP)

(21) Appl. No.: 19/391,486

(22) Filed: Nov. 17, 2025

Related U.S. Application Data
(63) Continuation of application No. PCT/JP2024/015708, filed on Apr. 22, 2024.

(30) Foreign Application Priority Data
May 23, 2023 (JP) 2023-084535
Feb. 15, 2024 (JP) 2024-021348

(51) Int. Cl. H10D 30/47; H10D 62/17; H10D 64/23

(52) U.S. Cl. CPC H10D 30/477; H10D 30/478; H10D 62/221; H10D 64/252

(57) ABSTRACT

A nitride semiconductor device includes a substrate, a first nitride semiconductor layer, a first p-type nitride semiconductor layer and a second nitride semiconductor layer disposed sequentially from below; an electron transport layer and an electron supply layer arranged sequentially from below to cover a first opening and the second nitride semiconductor layer, the first opening penetrating through the second nitride semiconductor layer and the first p-type nitride semiconductor layer; a second p-type nitride semiconductor layer or an insulating layer disposed in a position overlapping with a bottom surface of the first opening; a gate electrode disposed in a position overlapping with the second nitride semiconductor layer; a first source electrode disposed to cover a second opening penetrating through the electron supply layer and the electron transport layer; a drain electrode; and a second source electrode disposed above the second p-type nitride semiconductor layer or the insulating layer.

### CROSS REFERENCE TO RELATED APPLICATIONS

This is a continuation application of PCT International Application No. PCT/JP2024/015708 filed on Apr. 22, 2024, designating the United States of America, which is based on and claims priority of Japanese Patent Application No. 2023-084535 filed on May 23, 2023, and Japanese Patent Application No. 2024-021348 filed on Feb. 15, 2024. The entire disclosures of the above-identified applications, including the specifications, drawings and claims are incorporated herein by reference in their entirety.

### FIELD

The present disclosure relates to a nitride semiconductor device.

### BACKGROUND

Nitride semiconductors represented by GaN are wide bandgap semiconductors with a large bandgap, and have features such as a large dielectric breakdown electric field and a saturated drift rate of electrons higher than those of compound semiconductors such as GaAs or Si semiconductors. For example, the bandgap of GaN and that of AlN are 3.4 eV and 6.2 eV at room temperature, respectively. For this reason, research and development of power transistors including a nitride semiconductor that advantageously increases output and/or breakdown voltage have been actively conducted.

In an AlGaN/GaN hetero-structure, a high concentration of a two-dimensional electron gas (2DEG) is generated at the hetero-interface due to spontaneous polarization and piezoelectric polarization on the (0001) plane, and a sheet carrier concentration of 1×10¹³ cm⁻² or more is obtained even without doping.

Patent Literature (PTL) 1 and 2 and Non-Patent Literature 1 disclose vertical field effect transistors (FET) formed using a GaN semiconductor material. In the vertical FETs disclosed in PTLs 1 and 2, the operation of the transistor is implemented by opening and closing a channel with the gate voltage, the channel being formed by the two-dimensional electron gas generated at the AlGaN/GaN hetero-interface.

### CITATION LIST

### Patent Literature

PTL 1: Japanese Patent No. 6511645
PTL 2: Japanese Patent No. 6755892

### Non Patent Literature

NPL 1: Zhu et al., “Vertical GaN Power Transistor With Intrinsic Reverse Conduction and Low Gate Charge for High-Performance Power Conversion”, IEEE Journal of Emerging and Selected Topics in Power Electronics, Vol. 7, No. 3, September 2019

### SUMMARY

### Technical Problem

The traditional nitride semiconductor devices can be improved upon an increase in operational speed.

Thus, the present disclosure provides a nitride semiconductor device enabling high-speed operation.

### Solution to Problem

The nitride semiconductor device according to one aspect of the present disclosure includes a substrate; a first nitride semiconductor layer disposed above the substrate; a first p-type nitride semiconductor layer disposed above the first nitride semiconductor layer; a second nitride semiconductor layer disposed above the first p-type nitride semiconductor layer; an electron transport layer and an electron supply layer arranged sequentially from below to cover a lateral surface and a bottom surface of a first opening and an upper surface of the second nitride semiconductor layer, the first opening penetrating through the second nitride semiconductor layer and the first p-type nitride semiconductor layer and reaching the first nitride semiconductor layer; a second p-type nitride semiconductor layer or an insulating layer disposed above the electron supply layer in a position overlapping with the bottom surface of the first opening in the planar view of the substrate; a gate electrode disposed above the electron supply layer in a position overlapping with the second nitride semiconductor layer in the planar view of the substrate; a first source electrode disposed to cover a second opening and electrically connected to the first p-type nitride semiconductor layer, the second opening being disposed in a position away from the gate electrode in the planar view of the substrate and penetrating through the electron supply layer and the electron transport layer and reaching the first p-type nitride semiconductor layer; a drain electrode disposed below the substrate; and a second source electrode disposed above the second p-type nitride semiconductor layer or the insulating layer and electrically connected to the first source electrode.

### Advantageous Effects

The present disclosure provides a nitride semiconductor device enabling high-speed operation.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a nitride semiconductor device according to Embodiment 1.

FIG. 2A is a cross-sectional view for illustrating the gate-drain parasitic capacitance of a nitride semiconductor device according to Comparative Example.

FIG. 2B is a cross-sectional view for illustrating the gate-drain parasitic capacitance of the nitride semiconductor device according to Embodiment 1.

FIG. 3 is a cross-sectional view of a nitride semiconductor device according to Embodiment 2.

FIG. 4 is a cross-sectional view of a nitride semiconductor device according to Embodiment 3.

FIG. 5 is a cross-sectional view of a modification of the nitride semiconductor device according to Embodiment 3.

FIG. 6 is a cross-sectional view of a nitride semiconductor device according to Embodiment 4.

FIG. 7 is a cross-sectional view of a modification of the nitride semiconductor device according to Embodiment 4.

FIG. 8 is a cross-sectional view of a nitride semiconductor device according to Embodiment 5.

FIG. 9A is a cross-sectional view for illustrating the gate-drain parasitic capacitance of a nitride semiconductor device according to Comparative Example.

FIG. 9B is a cross-sectional view for illustrating the gate-drain parasitic capacitance of the nitride semiconductor device according to Embodiment 5.

FIG. 10 is a cross-sectional view of a nitride semiconductor device according to Modification 1 of Embodiment 5.

FIG. 11 is a cross-sectional view of a nitride semiconductor device according to Embodiment 6.

FIG. 12 is a cross-sectional view of a nitride semiconductor device according to Embodiment 7.

FIG. 13 is a cross-sectional view of a nitride semiconductor device according to Embodiment 8.

FIG. 14 is a cross-sectional view of a nitride semiconductor device according to Embodiment 9.

FIG. 15 is a cross-sectional view of a nitride semiconductor device according to Embodiment 10.

### DESCRIPTION OF EMBODIMENTS

### (Underlying Knowledge Forming Basis of the Present Disclosure)

The present inventors have found that the traditional nitride semiconductor devices described in “Background” have the following problems.

Compared to the horizontal transistor, the vertical transistor has advantages for an increase in voltage and operation at a large current. On the other hand, compared to the horizontal transistor, the vertical transistor has a disadvantage for the operation at a high speed as described below.

The vertical transistor has a configuration in which the substrate is disposed between the source and the drain. For this reason, in the vertical transistor, the drain current flowing between the source and the drain mainly flows in a direction intersecting perpendicular to the main surface of the substrate. In contrast, the horizontal transistor has a configuration in which the source and drain are arranged in a direction parallel to the main surface of the substrate. For this reason, in the horizontal transistor, the drain current mainly flows in the direction parallel to the main surface of the substrate.

TABLE 1

| | Horizontal GaN Tr | | Vertical GaN Tr | |
|---|---|---|---|---|
| On-resistance Ron | 100 | mΩ | 100 | mΩ |
| Gate-drain parasitic capacity | 2.56 | pF | 152 | pF |

Cgd@Vd = 300 V

Table 1 shows comparison between gate-drain parasitic capacitance Cgd of the horizontal transistor and that of the vertical transistor. Gate-drain parasitic capacitance Cgd of the vertical transistor is about two orders of magnitude greater than that of the horizontal transistor having a device size to provide on-resistance Ron identical to that of the vertical transistor. This is caused by a large parallel plate capacitance between the gate and the drain due to the structure of the vertical transistor and by difficulties in disposing a field plate for terminating electric lines of force from the drain toward the gate in the source. Large parasitic capacitance Cgd impairs rising properties of the drain current, which makes it difficult for the transistor to operate at a high speed.

In Patent Literature 1, a p-type GaN layer and a gate electrode are arranged along the inner side of a gate opening. The electric field is likely to concentrate on the connection portion between the inclined surface of the gate opening and the bottom surface thereof. The electric field is relaxed because the p-type GaN layer is disposed on this portion. Such a configuration can increase the breakdown voltage of the device. However, this configuration increases the area of the p-type GaN layer and that of the gate electrode in order to relax the electric field, and thus cannot reduce parasitic capacitance Cgd.

Patent Literature 2 discloses a structure in which the gate electrode is disposed above the outer edge portion of the gate opening, but not inside the gate opening. In the configuration disclosed in Patent Literature 2, the gate drive voltage can be reduced, and an effect of reducing drive loss is demonstrated. However, in this structure, all the electric lines of force from the drain toward the gate go toward the gate, and thus this structure does not lead to a reduction in parasitic capacitance Cgd.

Non-Patent Literature 1 also describes the results of calculation indicating that the gate capacitance is reduced by a vertical transistor including a Schottky electrode connected to a source electrode, the Schottky electrode being disposed on a regrowth AlGaN layer. The Schottky barrier junction connected to the source acts as a Schottky diode in a reverse conducting mode. Since the diode can reduce the threshold, it is indicated that conduction loss can be reduced. Note that when the Schottky electrode disposed above the regrowth AlGaN layer is used as a field plate, the reverse characteristics of the Schottky characteristics are a larger leakage current and a smaller breakdown voltage than those of the reverse characteristics of the pn diode. For this reason, such reverse characteristics lead to a reduction in reliability of the transistor.

Thus, in consideration of such problems, an object of the present disclosure is to provide a nitride semiconductor device enabling high-speed operation by reducing parasitic capacitance Cgd while suppressing a reduction in reliability.

To achieve the above object, aspects of the nitride semiconductor devices according to the present disclosure have configurations described below.

The nitride semiconductor device according to a first aspect of the present disclosure includes a substrate; a first nitride semiconductor layer disposed above the substrate; a first p-type nitride semiconductor layer disposed above the first nitride semiconductor layer; a second nitride semiconductor layer disposed above the first p-type nitride semiconductor layer; an electron transport layer and an electron supply layer arranged sequentially from below to cover a lateral surface and a bottom surface of a first opening and an upper surface of the second nitride semiconductor layer, the first opening penetrating through the second nitride semiconductor layer and the first p-type nitride semiconductor layer and reaching the first nitride semiconductor layer; a second p-type nitride semiconductor layer or an insulating layer disposed above the electron supply layer in a position overlapping with the bottom surface of the first opening in the planar view of the substrate; a gate electrode disposed above the electron supply layer in a position overlapping with the second nitride semiconductor layer in the planar view of the substrate; a first source electrode disposed to cover a second opening and electrically connected to the first p-type nitride semiconductor layer, the second opening being disposed in a position away from the gate electrode in the planar view of the substrate and penetrating through the electron supply layer and the electron transport layer and reaching the first p-type nitride semiconductor layer; a drain electrode disposed below the substrate; and a second source electrode disposed above the second p-type nitride semiconductor layer or the insulating layer and electrically connected to the first source electrode.

Thereby, electric lines of force extending from the drain electrode can be terminated in the second source electrode disposed above the second p-type nitride semiconductor layer or the insulating layer and in the first p-type nitride semiconductor layer, and thus gate-drain parasitic capacitance Cgd can be reduced. Thus, this aspect can implement a nitride semiconductor device enabling high-speed operation.

In the nitride semiconductor device according to this aspect, because reverse characteristics of the pn diode including the second p-type nitride semiconductor layer (p) and the two-dimensional electron gas (n) generated in the interface between the electron supply layer and the electron transport layer can be used, an increase in leakage current and a reduction in breakdown voltage can be suppressed. Also when an insulating layer is disposed instead of the second p-type nitride semiconductor layer, an increase in leakage current and a reduction in breakdown voltage can be suppressed. Thus, a reduction in reliability of the nitride semiconductor device can be suppressed.

The nitride semiconductor device according to a second aspect of the present disclosure is the nitride semiconductor device according to the first aspect of the present disclosure, in which the lateral surface of the first opening is inclined relative to the bottom surface of the first opening, an upper surface of the electron supply layer includes a flat portion along the bottom surface of the first opening and an inclined portion along the lateral surface of the first opening, and the second p-type nitride semiconductor layer or the insulating layer continuously covers the flat portion and part of the inclined portion.

Thereby, because the electric field concentrating on the second nitride semiconductor layer in the off state can be dispersed, the leakage current in the off state can be reduced. According to this aspect, in addition to the effect of reducing gate-drain parasitic capacitance Cgd, relaxation of the electric field in the off state is promoted and favorable off properties are obtained.

The nitride semiconductor device according to a third aspect of the present disclosure is the nitride semiconductor device according to the first or second aspect of the present disclosure further including a third p-type nitride semiconductor layer disposed between the gate electrode and the electron supply layer to be spaced from the second p-type nitride semiconductor layer or the insulating layer.

Thereby, the carrier concentration immediately below the gate electrode can be reduced, and the threshold voltage of the transistor can be shifted to the positive side. Thus, the nitride semiconductor device according to this aspect can be easily implemented as a normally-off FET.

The nitride semiconductor device according to a fourth aspect of the present disclosure is the nitride semiconductor device according to the third aspect of the present disclosure, in which in the planar view of the substrate, a distance between the first p-type nitride semiconductor layer and the second p-type nitride semiconductor layer or the insulating layer is shorter than a distance between the third p-type nitride semiconductor layer and the second p-type nitride semiconductor layer or the insulating layer.

Thereby, larger part of electric lines of force extending from the drain electrode can be terminated in the first p-type nitride semiconductor layer, and thus gate-drain parasitic capacitance Cgd can be further reduced. Thus, this aspect can implement a nitride semiconductor device excellent in high-speed operation.

The nitride semiconductor device according to a fifth aspect of the present disclosure is the nitride semiconductor device according to the third aspect, in which in the planar view of the substrate, a distance between the third p-type nitride semiconductor layer and the second p-type nitride semiconductor layer or the insulating layer is shorter than a distance between the first p-type nitride semiconductor layer and the second p-type nitride semiconductor layer or the insulating layer.

Thereby, although gate-drain parasitic capacitance Cgd is slightly increased, the length of the gate is increased, and thus the breakdown voltage in the off state can be improved. This aspect can implement a nitride semiconductor device having excellent off properties and enabling high-speed operation.

The nitride semiconductor device according to a sixth aspect of the present disclosure is the nitride semiconductor device according to any one of the first to fifth aspects, in which a distance between the second p-type nitride semiconductor layer or the insulating layer and the drain electrode is shorter than a distance between the first p-type nitride semiconductor layer and the drain electrode.

Thereby, concentration of the electric field in the off state can be relaxed, and the leakage current in the off state can be reduced. This aspect can implement a nitride semiconductor device having favorable off properties and enabling high-speed operation.

The nitride semiconductor device according to a seventh aspect of the present disclosure is the nitride semiconductor device according to the first aspect, in which the nitride semiconductor device includes the second p-type nitride semiconductor layer among the second p-type nitride semiconductor layer and the insulating layer, the second p-type nitride semiconductor layer is further disposed in a position overlapping with the lateral surface of the first opening in the planar view of the substrate, the second source electrode is further electrically connected to the second p-type nitride semiconductor layer, and part of a lower surface of the second p-type nitride semiconductor layer is located in a position higher than an opening surface of the first opening.

The nitride semiconductor device according to the seventh aspect of the present disclosure can be put it another way as follows. That is, the nitride semiconductor device according to the seventh aspect of the present disclosure includes a substrate; a first nitride semiconductor layer disposed above the substrate; a first p-type nitride semiconductor layer disposed above the first nitride semiconductor layer; a second nitride semiconductor layer disposed above the first p-type nitride semiconductor layer; an electron transport layer and an electron supply layer arranged sequentially from below to cover a lateral surface and a bottom surface of a first opening and an upper surface of the second nitride semiconductor layer, the first opening penetrating through the second nitride semiconductor layer and the first p-type nitride semiconductor layer and reaching the first nitride semiconductor layer; a second p-type nitride semiconductor layer disposed above the electron supply layer in a position overlapping with the bottom surface and lateral surface of the first opening in the planar view of the substrate; a gate electrode disposed above the electron supply layer in a position overlapping with the second nitride semiconductor layer in the planar view of the substrate; a first source electrode disposed in a position away from the gate electrode to cover a second opening disposed and electrically connected to the first p-type nitride semiconductor layer, the second opening penetrating through the electron supply layer and the electron transport layer and reaching the first p-type nitride semiconductor layer in the planar view of the substrate; a drain electrode disposed below the substrate; and a second source electrode disposed above the second p-type nitride semiconductor layer and electrically connected to the second p-type nitride semiconductor layer and the first source electrode, in which part of a lower surface of the second p-type nitride semiconductor layer is located in a position higher than the opening surface of the first opening.

In the nitride semiconductor device according to this aspect, the first p-type nitride semiconductor layer and the second p-type nitride semiconductor layer are both electrically connected to the first source electrode. Thus, the first p-type nitride semiconductor layer and the second p-type nitride semiconductor layer are fixed to the potential applied to the first source electrode (i.e., source potential). Thereby, electric lines of force extending from the drain electrode can be terminated in the first p-type nitride semiconductor layer and the second p-type nitride semiconductor layer, and thus gate-drain parasitic capacitance Cgd can be reduced. Thus, this aspect can implement a nitride semiconductor device enabling high-speed operation.

Since the nitride semiconductor device according to this aspect can use the reverse characteristics of the pn diode including the second p-type nitride semiconductor layer (p) and the two-dimensional electron gas (n) generated at the interface between the electron supply layer and the electron transport layer, an increase in leakage current and a reduction in breakdown voltage can be suppressed. Thus, a reduction in reliability of the nitride semiconductor device can be suppressed.

The nitride semiconductor device according to an eighth aspect of the present disclosure is the nitride semiconductor device according to the seventh aspect, in which the lateral surface of the first opening is inclined relative to the bottom surface of the first opening, an upper surface of the electron supply layer includes: a flat portion along the bottom surface of the first opening; an inclined portion along the lateral surface of the first opening; and an outer edge portion extending from an upper end of the inclined portion in a direction away from the flat portion; and the lower surface of the second p-type nitride semiconductor layer continuously covers at least part of the flat portion, the inclined portion, and part of the outer edge portion.

Thereby, the second p-type nitride semiconductor layer can continuously cover a large area of the upper surface of the electron supply layer from the flat portion to the outer edge portion. Since the second p-type nitride semiconductor layer can be disposed even in a portion near the gate electrode disposed above the outer edge portion and the effect of terminating electric lines of force can be increased, the effect of reducing parasitic capacitance Cgd can be enhanced.

The nitride semiconductor device according to a ninth aspect of the present disclosure is the nitride semiconductor device according to the seventh or eighth aspect, in which in the planar view of the substrate, the second p-type nitride semiconductor layer overlaps with the first p-type nitride semiconductor layer.

Thereby, by overlapping of the first p-type nitride semiconductor layer and the second p-type nitride semiconductor layer in the planar view of the substrate, the gate electrode cannot be seen from the drain electrode side. Thus, the effect of reducing parasitic capacitance Cgd can be further enhanced.

The nitride semiconductor device according to a tenth aspect of the present disclosure is the nitride semiconductor device according to any one of the seventh to ninth aspects further including a third p-type nitride semiconductor layer disposed between the gate electrode and the electron supply layer to be spaced from the second p-type nitride semiconductor layer.

Thereby, the carrier concentration immediately below the gate electrode can be reduced, and the threshold voltage of the transistor can be shifted to the positive side. For this reason, the nitride semiconductor device according to this aspect can be easily implemented as a normally-off FET.

The nitride semiconductor device according to an eleventh aspect of the present disclosure is the nitride semiconductor device according to any one of the seventh to tenth aspects further including an insulating film disposed between the gate electrode and the electron supply layer.

Thereby, the nitride semiconductor device according to this aspect can be implemented as a metal-insulator-semiconductor FET (MISFET). Since any semiconductor layer need not to be disposed between the gate electrode and the electron supply layer, the number of times to perform epitaxial growth can be reduced, and the production process can be simplified and costs can be reduced. The simplification of the production process leads to an improvement in yield and an improvement in reliability of the nitride semiconductor device to be manufactured.

The nitride semiconductor device according to a twelfth aspect of the present disclosure is the nitride semiconductor device according to any one of the seventh to eleventh aspects, in which the electron supply layer includes an impurity region disposed in a position overlapping with the gate electrode in the planar view of the substrate.

Thereby, the carrier concentration immediately below the gate electrode can be reduced, and the threshold voltage of the transistor can be shifted to the positive side. Thus, the nitride semiconductor device according to this aspect can be easily implemented as a normally-off FET. The impurity region can be locally formed by ion injection, for example. The number of times to perform epitaxial growth can be reduced, and the production process can be simplified and costs can be reduced.

The nitride semiconductor device according to a thirteenth aspect of the present disclosure is the nitride semiconductor device according to any one of the seventh to twelfth aspects, in which a depressed portion is disposed in the electron supply layer in a position overlapping with the gate electrode in the planar view of the substrate.

Thereby, the carrier concentration immediately below the gate electrode can be reduced, and the threshold voltage of the transistor can be shifted to the positive side. Thus, the nitride semiconductor device according to this aspect can be easily implemented as a normally-off FET. The recess can be locally formed by etching, for example. The number of times to perform epitaxial growth can be reduced, and the production process can be simplified and costs can be reduced.

The nitride semiconductor device according to a fourteenth aspect of the present disclosure is the nitride semiconductor device according to any one of the seventh to thirteenth aspects, in which a distance between the second p-type nitride semiconductor layer and the drain electrode is shorter than a distance between the first p-type nitride semiconductor layer and the drain electrode.

Thereby, the electric field attributed to the voltage applied between the source and the drain is more likely to concentrate on the lower surface of the second p-type nitride semiconductor layer than on the first p-type nitride semiconductor layer. When the lateral surface of the first opening is inclined, the lateral surface of the first p-type nitride semiconductor layer is at an acute angle and becomes weak against the concentration of the electric field. In this aspect, in which the electric field is likely to concentrate on the lower surface of the second p-type nitride semiconductor layer, the breakdown voltage of the nitride semiconductor device can be increased.

The nitride semiconductor device according to a fifteenth aspect of the present disclosure is the nitride semiconductor device according to any one of the seventh to fourteenth aspects, in which the second p-type nitride semiconductor layer includes a third opening that penetrates through the second p-type nitride semiconductor layer and reaches the electron supply layer, and the second source electrode is in contact with the electron supply layer in a bottom surface of the third opening.

Thereby, a junction barrier Schottky (JBS) structure including a pn diode and a Schottky diode is formed near the third opening. The JBS structure has a threshold voltage smaller than that of the pn diode alone. For this reason, the threshold voltage is reduced when the nitride semiconductor device operates in a reverse conducting mode, thus reducing the drive voltage. Thus, conduction loss of the reverse conducting mode can be reduced.

Hereinafter, embodiments according to the present disclosure will be described with reference to the drawings.

The embodiments described below all illustrate general or specific examples. Numeric values, shapes, materials, components, arrangement positions of components and connection forms thereof, steps, order of steps, and the like shown in embodiments below are exemplary, and should not be construed as limitations to the present disclosure. Moreover, among the components of the embodiments below, the components not described in an independent claim will be described as optional components.

The drawings are schematic views, and are not necessarily precise illustrations. Accordingly, for example, the scale is not always consistent among the drawings. In the drawings, identical reference signs are given to substantially identical configurations, and the duplication of the description will be omitted or simplified.

In this specification, terms representing relations between entities, such as parallel or orthogonal, terms representing shapes of entities, such as rectangular or trapezoidal, and numeric value ranges are not expressions representing only strict meanings, but are expressions meaning substantially equal ranges, for example, those also containing differences of about several percentage.

In this specification, the term “thickness direction” of the substrate indicates the direction vertical to the main surface of the substrate. The thickness direction is the same as the stacking direction of the semiconductor layer, and is also referred to as “vertical direction”. The direction parallel to the main surface of the substrate may be referred to as “horizontal direction” in some cases.

The side of the substrate on which the gate electrode and the source electrode are disposed is regarded as “above” or “upper side”, and the side of the substrate on which the drain electrode is disposed is regarded as “below” or “lower side”.

In this specification, the terms “above” and “below” do not indicate an upper direction (upper in the vertical direction) and a lower direction (lower in the vertical direction) in absolute spatial recognition, but are used as terms specified by relative positional relation based on the stacking order of the stacking configuration. The terms “above” and “below” are used not only when two components are arranged with an interval and another component is present between the two components, but also when two components are disposed in close contact with each other.

In this specification, unless otherwise specified, the expression “in the planar view” indicates viewing of the nitride semiconductor device in a direction vertical to the main surface of the substrate, that is, viewing of the main surface of the substrate from the front side.

In this specification, the expression “distance between A and B in the planar view” indicates the shortest distance between A and B in the planar view. Specifically, in the planar view, among countless line segments connecting any point on the contour representing the outline of A and any point on the contour representing the outline of B, the length of the shortest line segment is the distance.

In this specification, the expression “A overlaps with B in the planar view” means that at least part of A overlaps with at least part of B. In other words, the expression includes the case where only part of A overlaps with only part of B, the case where all of A overlaps with all of B, the case where all of B overlaps with A, and the case where A and B completely overlap with each other.

In this specification, unless otherwise specified, ordinals such as “first” and “second” do not mean the number or order of components, but are used to avoid confusion of components of similar types and distinguish these.

In this specification, AlGaN represents a tertiary mixed crystal AlₓGa₁₋ₓN (where 0<x<1). Hereinafter, multicomponent mixed crystals are abbreviated based on arrangement of constitutional element symbols, such as AlInN and GaInN, for example. For example, AlₓGa_{1-x-y}In_{y}N (where 0<x<1, 0<y<1, and 0<x+y<1) as one example of the nitride semiconductor is abbreviated to AlGaInN.

### Embodiment 1

### [Configuration]

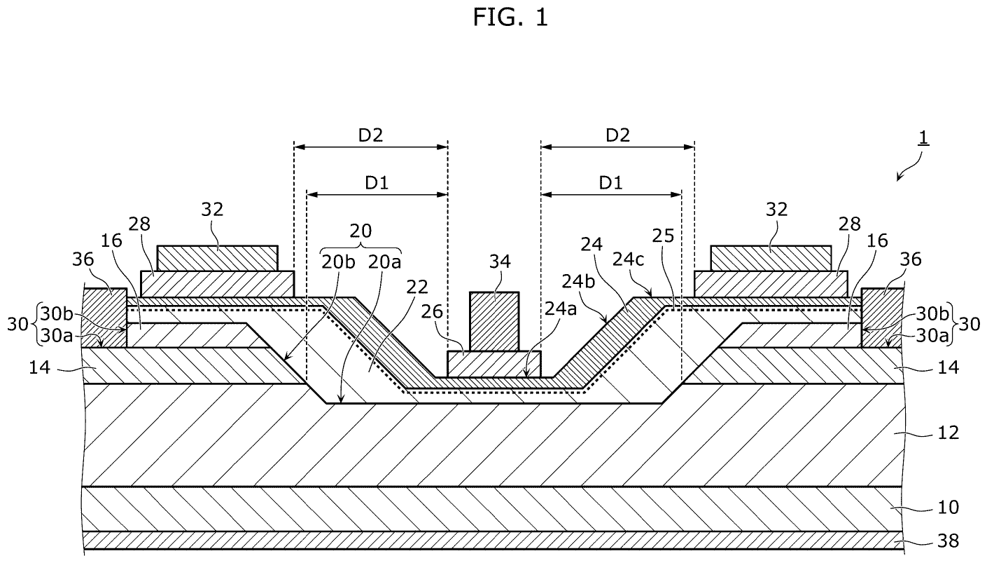

First, the configuration of the nitride semiconductor device according to Embodiment 1 will be described with reference to FIG. 1.

FIG. 1 is a cross-sectional view of nitride semiconductor device 1 according to the present embodiment. In FIG. 1, the components such as semiconductor layers and electrodes are hatched, which indicates cross-sectional views.

As illustrated in FIG. 1, nitride semiconductor device 1 according to the present embodiment is a so-called vertical field effect transistor (FET). Specifically, in nitride semiconductor device 1, a current flows between drain electrode 38 and first source electrode 36 in a direction vertical to a main surface of substrate 10.

Nitride semiconductor device 1 is a device having a stacking structure of nitride semiconductor layers containing nitride semiconductors such as GaN and AlGaN as the main components. The expression “A contains B as the main component” means that among the substances contained in A, the content of B is the maximum. For example, the content of B in A is 50% or more.

Nitride semiconductor device 1 according to the present embodiment is a normally-off FET. In nitride semiconductor device 1, for example, first source electrode 36 is grounded (namely, the potential is 0 V), and a positive potential is given to drain electrode 38. The potential given to drain electrode 38 is 100 V or more and 1200 V or less, for example, but not limited thereto. When nitride semiconductor device 1 is in an off state, 0 V or a negative potential (for example, −5 V) is applied to gate electrode 32. When nitride semiconductor device 1 is an on state, a positive potential (for example, +5 V) is applied to gate electrode 32. Nitride semiconductor device 1 may be a normally-on FET.

As illustrated in FIG. 1, nitride semiconductor device 1 includes substrate 10, drift layer 12, block layer 14, underlying layer 16, vertical conduction opening 20, electron transport layer 22, electron supply layer 24, p-type semiconductor layer 26, threshold adjustment layer 28, source opening 30, gate electrode 32, second source electrode 34, first source electrode 36, and drain electrode 38. Two-dimensional electron gas (2DEG) 25 that functions as a channel is generated at the interface between electron transport layer 22 and electron supply layer 24.

Hereinafter, details of the components included in nitride semiconductor device 1 will be described.

Substrate 10 is a nitride semiconductor substrate. Substrate 10 is in a rectangular shape in the planar view, for example, but can be in any other shape.

For example, substrate 10 is an n⁺-type GaN substrate with a thickness of 300 μm and a carrier concentration of 1×10¹⁸ cm⁻³. The n-type and the p-type each indicate a conductivity type of a semiconductor. The n⁺-type indicates a state where a high concentration of an n-type dopant is added to the semiconductor, or the semiconductor is heavily doped with the n-type dopant. The n-type indicates a state where a low concentration of an n-type dopant is added to the semiconductor, or the semiconductor is lightly doped with the n-type dopant. The n⁺-type and the n-type are one examples of the n-type, and may be collectively referred to as n-type. The same is applied to the p⁺-type and the p⁻-type.

Substrate 10 need not to be a nitride semiconductor substrate. For example, substrate 10 may be a silicon (Si) substrate, a silicon carbide (SiC) substrate, or a zinc oxide (ZnO) substrate.

Drift layer 12 is one example of the first nitride semiconductor layer disposed above substrate 10. For example, drift layer 12 is an n-type GaN film with a thickness of 8 μm. The donor concentration in drift layer 12 is, for example, 1×10¹⁵ cm⁻³ or more and 1×10¹⁷ cm⁻³ or less, and as one example, 1×10¹⁶ cm⁻³. The carbon concentration (C concentration) in drift layer 12 is, for example, 1×10¹⁵ cm⁻³ or more and 2×10¹⁷ cm⁻³ or less.

For example, drift layer 12 is disposed in contact with the upper surface (main surface) of substrate 10. Drift layer 12 is formed on the main surface of substrate 10 by crystal growth such as metal organic vapor phase epitaxy (MOVPE) or hydride vapor phase epitaxy (HVPE).

Block layer 14 is one example of the first p-type nitride semiconductor layer disposed above drift layer 12. For example, block layer 14 is a p-type GaN film with a thickness of 400 nm and a carrier concentration of 1×10¹⁷ cm⁻³. Block layer 14 is disposed in contact with the upper surface of drift layer 12. Block layer 14 is formed above drift layer 12 by crystal growth such as MOVPE or HVPE, for example.

Although block layer 14 is formed by crystal growth, block layer 14 may be formed by injecting magnesium (Mg) to the obtained i-GaN film, for example. Additionally, block layer 14 may be an insulating layer obtained by injecting iron (Fe) or boron (B), but not a p-type nitride semiconductor layer.

Block layer 14 suppresses a leakage current between first source electrode 36 and drain electrode 38. For example, when a reverse voltage is applied to a pn junction formed by block layer 14 and drift layer 12, specifically, when the potential of drain electrode 38 is higher than that of first source electrode 36, a depletion layer extends to drift layer 12. Thereby, the breakdown voltage of nitride semiconductor device 1 can be increased. In the present embodiment, the potential of drain electrode 38 is higher than that of first source electrode 36 in both of the off state and the on state (excluding the reverse conducting operation). For this reason, the breakdown voltage of nitride semiconductor device 1 can be increased.

In the present embodiment, as illustrated in FIG. 1, block layer 14 is in contact with first source electrode 36. For this reason, the potential of block layer 14 is fixed to the source potential applied to first source electrode 36. Thereby, block layer 14 can block electric lines of force extending from drain electrode 38 and can contribute to a reduction in gate-drain parasitic capacitance Cgd, although details will be described later.

Underlying layer 16 is one example of the second nitride semiconductor layer disposed above block layer 14. Underlying layer 16 is a high-resistance layer having a resistance higher than that of block layer 14. For example, underlying layer 16 is an undoped GaN (i-GaN) film with a thickness of 200 nm. Underlying layer 16 is disposed in contact with block layer 14. Underlying layer 16 is formed above block layer 14 by crystal growth such as MOVPE or HVPE, for example.

It is assumed that underlying layer 16 is an undoped semiconductor layer, although it may be an insulating layer or a semi-insulating layer. Here, “undoped” means that the layer is not doped with a dopant that changes the polarity of GaN to the n-type or the p-type, such as Si or Mg. In the present embodiment, underlying layer 16 may be doped with carbon (C). For example, the carbon concentration in underlying layer 16 is higher than the carbon concentration in block layer 14.

For example, the carbon concentration in underlying layer 16 is 3×10¹⁷ cm⁻³ or more, and may be 1×10¹⁸ cm⁻³ or more. At this time, silicon (Si) or oxygen (O) as an n-type impurity is contained in a concentration lower than the carbon concentration. For example, the silicon concentration or oxygen concentration in underlying layer 16 is 5×10¹⁶ cm⁻³ or lower, and may be 2×10¹⁶ cm⁻³ or lower. The same effects as those described above can also be provided by any other ion species than the above-mentioned ion species injected to underlying layer 16 and block layer 14 as long as these ion species can increase the resistance of the semiconductor layer.

The upper surface of underlying layer 16 may include a layer for suppressing diffusion of a p-type impurity such as Mg from block layer 14. For example, an AlGaN layer with a thickness of 20 nm may be disposed above block layer 14.

Vertical conduction opening 20 is one example of the first opening that penetrates through underlying layer 16 and block layer 14 and reaches drift layer 12. Vertical conduction opening 20 can also be referred to as gate opening. Bottom surface 20a of vertical conduction opening 20 is part of the upper surface of drift layer 12. As illustrated in FIG. 1, bottom surface 20a is located in a position lower than that of the lower surface of block layer 14. The lower surface of block layer 14 corresponds to the interface between block layer 14 and drift layer 12. For example, bottom surface 20a is parallel with the main surface of substrate 10. The drain current when nitride semiconductor device 1 is on flows between drain electrode 38 and first source electrode 36 through bottom surface 20a of vertical conduction opening 20.

In the present embodiment, vertical conduction opening 20 is formed to have an opening area that becomes larger as it is farther away from substrate 10. Specifically, lateral surface 20b of vertical conduction opening 20 is inclined. The opening surface of vertical conduction opening 20 is larger than bottom surface 20a. As illustrated in FIG. 1, the shape of vertical conduction opening 20 in cross-sectional view is inverted trapezoidal, more specifically, inverted isosceles trapezoidal.

The opening surface of vertical conduction opening 20 is one example of the opening surface of the first opening. The outline of the opening surface of vertical conduction opening 20 corresponds to the upper end of lateral surface 20b. In the cross-section illustrated in FIG. 1, the line segment connecting the left upper end of lateral surface 20b to the right upper end of lateral surface 20b corresponds to the opening surface. The upper end of lateral surface 20b is the point of intersection of the upper surface of underlying layer 16 and the lateral surface of underlying layer 16. The opening surface of vertical conduction opening 20 may be regarded to be at the same height as that of the upper surface of underlying layer 16. The “height” is represented by the distance from the main surface of substrate 10.

The tilt angle of lateral surface 20b to bottom surface 20a is 20° or more and 90° or less, for example. The tilt angle may be 20° or more and 80° or less, or may be 30° or more and 45° or less. As the tilt angle is smaller, lateral surface 20b is closer to the c plane. Thus, the quality of the film formed along lateral surface 20b by crystal regrowth, such as electron transport layer 22, can be enhanced. On the other hand, a larger tilt angle suppresses excessively large vertical conduction opening 20, and thus the size of nitride semiconductor device 1 is reduced.

Vertical conduction opening 20 is formed by continuously forming drift layer 12, block layer 14, and underlying layer 16 above the main surface of substrate 10 in this order, and then removing part of underlying layer 16 and block layer 14 to partially expose drift layer 12. At this time, by removing a surface layer portion of drift layer 12 by a predetermined thickness (for example, 300 nm), bottom surface 20a of vertical conduction opening 20 is formed in a position lower than that of the lower surface of block layer 14.

As a method of removing underlying layer 16 and block layer 14, dry etching such as inductively coupled plasma etching (ICP) is used, and a chlorine-based gas is often used as a process gas.

Electron transport layer 22 is one example of the first regrowth layer disposed to cover the upper surface of underlying layer 16 and lateral surface 20b and bottom surface 20a of vertical conduction opening 20. Specifically, part of electron transport layer 22 is disposed along bottom surface 20a and lateral surface 20b of vertical conduction opening 20, and the remaining part of electron transport layer 22 is disposed above the upper surface of underlying layer 16. For example, electron transport layer 22 is an undoped GaN film with a thickness of 150 nm. It is assumed that electron transport layer 22 is undoped, although electron transport layer 22 may be partially doped with Si into the n-type.

Electron transport layer 22 is in contact with drift layer 12 in bottom surface 20a and lateral surface 20b of vertical conduction opening 20. Electron transport layer 22 is in contact with block layer 14 and underlying layer 16 in lateral surface 20b of vertical conduction opening 20. Furthermore, electron transport layer 22 is in contact with the upper surface of underlying layer 16.

Electron transport layer 22 includes a channel region. Specifically, two-dimensional electron gas 25 forming a channel is generated near the interface between electron transport layer 22 and electron supply layer 24. In FIG. 1, two-dimensional electron gas 25 schematically illustrated using is a dashed line. Two-dimensional electron gas 25 is bent along the interface between electron transport layer 22 and electron supply layer 24, that is, along the inner surface of vertical conduction opening 20.

Although not illustrated in FIG. 1, as the second regrowth layer, an AlN layer with a thickness of about 1 nm is disposed between electron transport layer 22 and electron supply layer 24. This can suppress alloy scattering, thus improving the channel mobility, and the on-resistance can be reduced. The AlN layer is not always needed.

Electron supply layer 24 is one example of the third regrowth layer disposed to cover the upper surface of underlying layer 16 and lateral surface 20b and bottom surface 20a of vertical conduction opening 20. Electron transport layer 22 and electron supply layer 24 are arranged in this order from substrate 10 side. Electron supply layer 24 is an undoped AlGaN film with a thickness of 20 nm, for example.

Electron supply layer 24 is formed into a shape along the upper surface of electron transport layer 22 to have a substantially uniform thickness. As illustrated in FIG. 1, the upper surface of electron supply layer 24 includes flat portion 24a, inclined portion 24b, and outer edge portion 24c.

Flat portion 24a is a portion along bottom surface 20a of vertical conduction opening 20. Flat portion 24a is a flat surface parallel to bottom surface 20a, for example. Flat portion 24a is a portion located in the lowest position in the upper surface of electron supply layer 24.

Inclined portion 24b is a portion along lateral surface 20b of vertical conduction opening 20. Inclined portion 24b is an inclined surface parallel to lateral surface 20b of vertical conduction opening 20, for example. Inclined portion 24b is disposed on both sides of flat portion 24a with flat portion 24a interposed therebetween.

Outer edge portion 24c is a portion that extends from the upper end of inclined portion 24b to a direction away from flat portion 24a. Here, the “direction away from flat portion 24a” is the direction toward first source electrode 36 from bottom surface 20a of vertical conduction opening 20 in the planar view of substrate 10. The “direction away from flat portion 24a” corresponds to the direction toward the outside of vertical conduction opening 20 in a plane parallel to the main surface of substrate 10. Outer edge portion 24c is a flat surface parallel to the main surface of substrate 10. Outer edge portion 24c is a portion located in the uppermost position in the upper surface of electron supply layer 24.

Flat portion 24a, inclined portion 24b, and outer edge portion 24c may be curved surfaces. Flat portion 24a and inclined portion 24b may be smoothly curved and connected. Outer edge portion 24c and inclined portion 24b may be smoothly curved and connected.

Electron supply layer 24 has a bandgap larger than that of electron transport layer 22. For this reason, an AlGaN/GaN hetero-interface is formed between electron supply layer 24 and electron transport layer 22. Electron supply layer 24 feeds electrons to a channel region (two-dimensional electron gas 25) formed in electron transport layer 22.

P-type semiconductor layer 26 is one example of the second p-type nitride semiconductor layer disposed above electron supply layer 24 in a position overlapping with bottom surface 20a of vertical conduction opening 20 in the planar view of substrate 10. Specifically, p-type semiconductor layer 26 is disposed in contact with flat portion 24a of the upper surface of electron supply layer 24. In the present embodiment, p-type semiconductor layer 26 is not in contact with inclined portion 24b. P-type semiconductor layer 26 is a p-type AlₓGa₁₋ₓN (where 0<x<1) film with a thickness of 100 nm and a carrier concentration of 1×10¹⁷ cm⁻³, for example.

P-type semiconductor layer 26 is disposed in a position away from threshold adjustment layer 28. Specifically, p-type semiconductor layer 26 is electrically separated from threshold adjustment layer 28. The lower surface of p-type semiconductor layer 26 is located in a position lower than that of at least outer edge portion 24c of the upper surface of electron supply layer 24. For example, at least part of p-type semiconductor layer 26 is located at the same height as that of block layer 14.

An insulating layer may be disposed instead of p-type semiconductor layer 26. The insulating layer has a monolayer or multi-layer structure of an insulative nitride or oxide film including SiN, SiO₂, AlN, or Al₂O₃.

Threshold adjustment layer 28 is one example of the third p-type nitride semiconductor layer disposed between gate electrode 32 and electron supply layer 24 to be spaced from p-type semiconductor layer 26. Threshold adjustment layer 28 is disposed above outer edge portion 24c of the upper surface of electron supply layer 24, and is in contact with electron supply layer 24 and gate electrode 32.

By disposing threshold adjustment layer 28, the potential of the channel portion is raised. For this reason, the threshold of the transistor can be increased, and a normally-off transistor can be implemented.

The thickness of threshold adjustment layer 28, the compositional ratio therein, and the carrier concentration therein are the same as the thickness of p-type semiconductor layer 26, the compositional ratio therein, and the carrier concentration therein, respectively. Threshold adjustment layer 28 is formed by patterning a nitride semiconductor film formed through the same film formation step as that of p-type semiconductor layer 26.

Threshold adjustment layer 28 need not to be disposed. For example, an insulating layer of SiN or SiO₂ may be disposed between gate electrode 32 and electron supply layer 24, instead of threshold adjustment layer 28. Thereby, the gate current can be suppressed, and the threshold can be shifted to a positive direction to implement the normally-off operation.

Electron transport layer 22, electron supply layer 24, p-type semiconductor layer 26, and threshold adjustment layer 28 are formed by forming vertical conduction opening 20, and then continuously forming nitride semiconductor films through a crystal regrowth step, followed by patterning in a predetermined shape. Specifically, the undoped GaN film as the base for electron transport layer 22, the undoped AlGaN film as the base for electron supply layer 24, and the p-type AlGaN film as the base for p-type semiconductor layer 26 and threshold adjustment layer 28 are continuously formed by MOVPE or HVPE. After the film formation, by removing part of the p-type AlGaN film by etching until the undoped AlGaN film is exposed, p-type semiconductor layer 26 and threshold adjustment layer 28 are formed. P-type semiconductor layer 26 and threshold adjustment layer 28 are electrically separated from each other. Furthermore, part of the undoped AlGaN film, part of the undoped GaN film, and part of underlying layer 16 are continuously removed by etching until block layer 14 is exposed. Thereby, source opening 30 that reaches block layer 14 is formed, and electron supply layer 24 and electron transport layer 22 patterned in a predetermined shape are formed.

Source opening 30 is one example of the second opening disposed in a position away from gate electrode 32 to penetrate through electron supply layer 24 and electron transport layer 22 and reach block layer 14 in the planar view of substrate 10. In the present embodiment, source opening 30 is disposed in a position away from both of vertical conduction opening 20 and threshold adjustment layer 28 in the planar view of substrate 10.

Bottom surface 30a of source opening 30 is part of the upper surface of block layer 14. As the example shown in FIG. 1, bottom surface 30a is flush with the lower surface of underlying layer 16, although not to limited thereto. Bottom surface 30a may be located in a position lower than the lower surface of underlying layer 16. The lower surface of underlying layer 16 corresponds to the interface between underlying layer 16 and block layer 14. Bottom surface 30a is parallel to the main surface of substrate 10, for example.

As illustrated in FIG. 1, source opening 30 is formed with a predetermined opening area irrespective of the distance from substrate 10. Specifically, lateral surface 30b of source opening 30 is vertical to bottom surface 30a. In other words, the cross-sectional shape of source opening 30 is a rectangular shape.

Alternatively, source opening 30 may be formed with an opening area that becomes larger as it is farther away from substrate 10. Specifically, lateral surface 30b of source opening 30 may be inclined. For example, the cross-sectional shape of source opening 30 may be inverted trapezoidal, more specifically, inverted isosceles trapezoidal. At this time, the tilt angle of lateral surface 30b to bottom surface 30a may be within the range of 30° or more and 60° or less, for example. Such an inclination of lateral surface 30b increases the contact area between first source electrode 36 and electron transport layer 22 (two-dimensional electron gas 25), which facilitates formation of an ohmic contact. Two-dimensional electron gas 25 is exposed to lateral surface 30b of source opening 30, and is connected to first source electrode 36.

By disposing source opening 30, the ohmic contact resistance between two-dimensional electron gas 25 functioning as the channel and first source electrode 36 can be reduced. Because block layer 14 can be electrically connected to first source electrode 36, the potential of block layer 14 can be stabilized and the effect of improving the breakdown voltage and the like can be obtained.

Gate electrode 32 is disposed above electron supply layer 24 in a position overlapping with underlying layer 16 in the planar view of substrate 10. Specifically, gate electrode 32 is disposed in contact with the upper surface of threshold adjustment layer 28.

Gate electrode 32 is formed using a conductive material such as a metal, for example. For example, for gate electrode 32, a material to be in ohmic contact with a p-type GaN layer can be used. For example, a palladium (Pd) material, a nickel (Ni) material, tungsten silicide (WSi), or gold (Au) can be used. Gate electrode 32 is formed by forming threshold adjustment layer 28, then forming source opening 30 or forming first source electrode 36 and second source electrode 34, and forming a conductive film by sputtering or deposition, followed by patterning of the obtained conductive film.

Second source electrode 34 is disposed above p-type semiconductor layer 26. Specifically, second source electrode 34 is disposed in contact with the upper surface of p-type semiconductor layer 26. Second source electrode 34 is not in contact with electron supply layer 24.

Second source electrode 34 is electrically connected to first source electrode 36. In other words, second source electrode 34 is an electrode to which the same source potential as that to first source electrode 36 is fed. Second source electrode 34 is not directly connected to two-dimensional electron gas 25. The drain current from drain electrode 38 flows through two-dimensional electron gas 25 to first source electrode 36.

Second source electrode 34 is formed using a conductive material such as a metal. Second source electrode 34 can be formed using the same material as that for first source electrode 36. For example, second source electrode 34 is formed, for example, by forming a conductive film by sputtering or deposition, and patterning the obtained conductive film.

First source electrode 36 is disposed to cover source opening 30. Specifically, first source electrode 36 is disposed in contact with bottom surface 30a and lateral surface 30b of source opening 30 to fill in source opening 30. First source electrode 36 is electrically connected to block layer 14 exposed to bottom surface 30a of source opening 30.

First source electrode 36 may be in contact with outer edge portion 24c of the upper surface of electron supply layer 24 corresponding to the edge of source opening 30. First source electrode 36 is in direct contact with two-dimensional electron gas 25 on lateral surface 30b of source opening 30. Thereby, the contact resistance between first source electrode 36 and two-dimensional electron gas 25 can be reduced.

First source electrode 36 is formed using a conductive material such as a metal. As the material for first source electrode 36, for example, a material, Ti/Al (stacking structure of a Ti layer and an Al layer), subjected to a heat treatment to form an ohmic contact with an n-type GaN layer can be used. First source electrode 36 is formed, for example, by forming a conductive film by sputtering or deposition and patterning the obtained conductive film. First source electrode 36 is formed by the same production process as that for second source electrode 34, for example.

Drain electrode 38 is disposed below substrate 10. Specifically, drain electrode 38 is disposed in contact with the lower surface of substrate 10.

Drain electrode 38 is formed using a conductive material such as a metal. As the material for drain electrode 38, like the material for first source electrode 36, for example, a material forming an ohmic contact with n-type GaN such as Ti/Al can be used. Drain electrode 38 is formed, for example, by forming a conductive film by sputtering or deposition, and patterning the obtained conductive film.

### [Characteristic Configuration]

Subsequently, a main characteristic configuration of nitride semiconductor device 1 according to the present embodiment will be described.

As described above, in nitride semiconductor device 1 according to the present embodiment, gate electrode 32 and threshold adjustment layer 28 are located outside vertical conduction opening 20, and second source electrode 34 and p-type semiconductor layer 26 are arranged near bottom surface 20a of vertical conduction opening 20. In other words, second source electrode 34 and p-type semiconductor layer 26 are located in a position lower than those of gate electrode 32 and threshold adjustment layer 28. It is sufficient that at least the lower surface of p-type semiconductor layer 26 is located in a position lower than the lower surface of threshold adjustment layer 28. Part of second source electrode 34 and p-type semiconductor layer 26 may be located above one of gate electrode 32 and threshold adjustment layer 28.

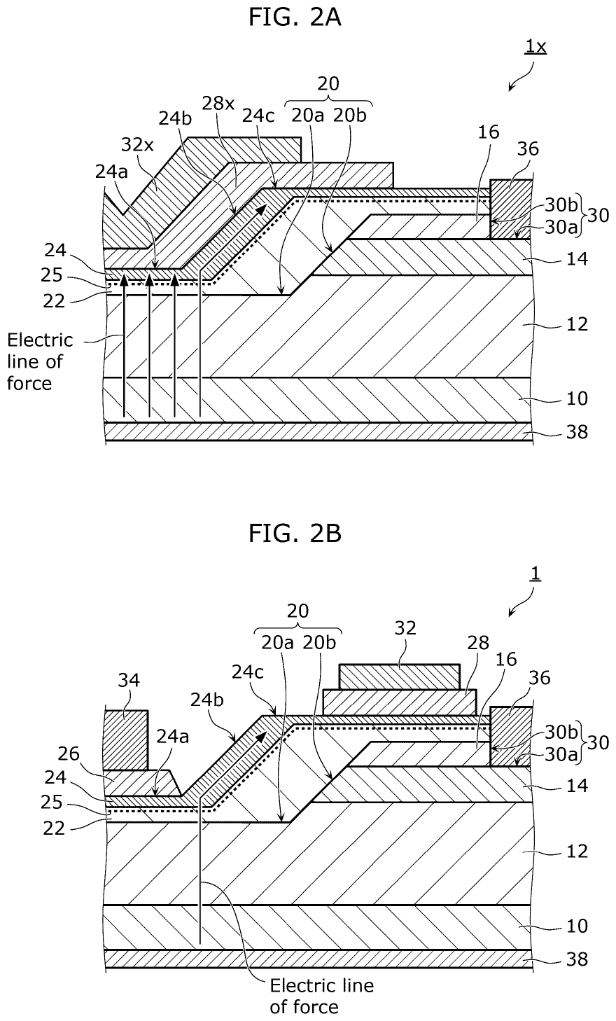

Hereinafter, with reference to FIGS. 2A and 2B, the configuration according to the present disclosure will be specifically described in comparison to Comparative Example. FIGS. 2A and 2B are diagrams for illustrating gate-drain parasitic capacitance Cgd in the nitride semiconductor device according to Comparative Example and that in the nitride semiconductor device according to the present embodiment.

FIG. 2A illustrates a portion near vertical conduction opening 20 in a cross-sectional configuration of nitride semiconductor device 1x according to Comparative Example. Compared to nitride semiconductor device 1, nitride semiconductor device 1x according to Comparative Example includes gate electrode 32x and threshold adjustment layer 28x instead of p-type semiconductor layer 26, threshold adjustment layer 28, gate electrode 32, and second source electrode 34. Specifically, gate electrode 32x and threshold adjustment layer 28x are arranged along bottom surface 20a and lateral surface 20b of vertical conduction opening 20. More specifically, threshold adjustment layer 28x is disposed to cover flat portion 24a, inclined portion 24b, and outer edge portion 24c of the upper surface of electron supply layer 24. Gate electrode 32x is disposed in contact with the upper surface of threshold adjustment layer 28x. Specifically, gate electrode 32x is disposed in a position overlapping with bottom surface 20a of vertical conduction opening 20 in the planar view.

In such a configuration, the area of a portion in which gate electrode 32x and threshold adjustment layer 28x face drain electrode 38 is increased. This results in a large parallel plate capacitance between the gate and the drain, and thus, substantially all the electric lines of force from the drain toward the gate that contribute to gate-drain parasitic capacitance Cgd are terminated in the gate. For this reason, parasitic capacitance Cgd is difficult to reduce.

On the other hand, in the configuration according to the present embodiment, as illustrated in FIG. 2B, second source electrode 34 and p-type semiconductor layer 26 are arranged near bottom surface 20a of vertical conduction opening 20. For this reason, part of the electric lines of force from the drain toward the gate can be terminated in second source electrode 34 and p-type semiconductor layer 26. As a result, gate-drain parasitic capacitance Cgd can be reduced.

As illustrated in FIG. 1, block layer 14 is located closer to p-type semiconductor layer 26 than to threshold adjustment layer 28. Specifically, in the planar view of substrate 10, distance D1 between block layer 14 and p-type semiconductor layer 26 is shorter than distance D2 between threshold adjustment layer 28 and p-type semiconductor layer 26. In other words, the end of block layer 14, which is connected to first source electrode 36, on p-type semiconductor layer 26 side is located close to p-type semiconductor layer 26 than the end of threshold adjustment layer 28 on p-type semiconductor layer 26 side. Thereby, block layer 14 can also block the electric lines of force to gate electrode 32. Thus, gate-drain parasitic capacitance Cgd can be further reduced, implementing a high speed operation of the transistor.

### Embodiment 2

Now, Embodiment 2 will be described.

In Embodiment 2, the position of the end of the threshold adjustment layer disposed immediately below the gate electrode is different from that in Embodiment 1. Hereinafter, differences from Embodiment 1 will be mainly described, and the descriptions of shared features will be omitted or simplified.

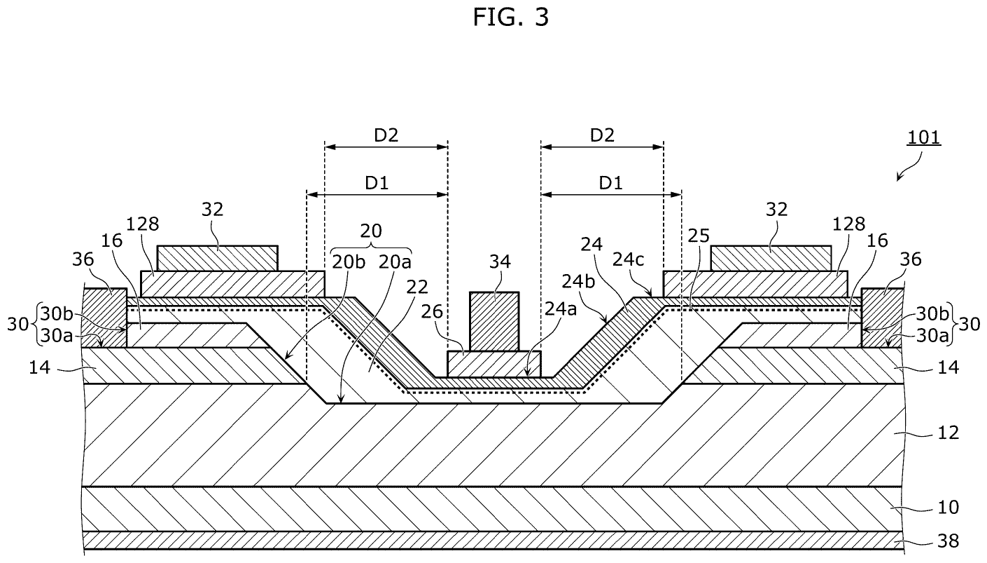

FIG. 3 is a cross-sectional view of nitride semiconductor device 101 according to Embodiment 2. As illustrated in FIG. 3, unlike nitride semiconductor device 1 illustrated in FIG. 1, nitride semiconductor device 101 includes threshold adjustment layer 128 instead of threshold adjustment layer 28. Threshold adjustment layer 128 is one example of the third p-type nitride semiconductor layer, and the position of the end is different from that of the end of threshold adjustment layer 28.

Specifically, in the planar view of substrate 10, distance D2 between threshold adjustment layer 128 and p-type semiconductor layer 26 is shorter than distance D1 between block layer 14 and p-type semiconductor layer 26. In other words, the end of threshold adjustment layer 128 on p-type semiconductor layer 26 side is located closer to p-type semiconductor layer 26 than the end of block layer 14 on p-type semiconductor layer 26 side is.

In such a configuration, part of the electric lines of force from drain electrode 38 to threshold adjustment layer 128 cannot be completely terminated in block layer 14 connected to first source electrode 36. For this reason, gate-drain parasitic capacitance Cgd is slightly increased compared to that of nitride semiconductor device 1 according to Embodiment 1. On the other hand, the length of the gate can be increased, and thus the off breakdown voltage of nitride semiconductor device 101 can be improved.

The length of the gate corresponds to a length which enables opening and closing of the channel by gate electrode 32 and threshold adjustment layer 28, and specifically indicates the length of threshold adjustment layer 128 in a direction in which first source electrode 36 and gate electrode 32 are aligned. The width of threshold adjustment layer 28 in cross-sectional view illustrated in FIG. 3 (length in the horizontal direction) corresponds to the length of the gate. The length of the gate can be increased by disposing the end of threshold adjustment layer 128 on p-type semiconductor layer 26 side to be closer to p-type semiconductor layer 26. For example, in the planar view, part of threshold adjustment layer 128 may overlap with bottom surface 20a of vertical conduction opening 20.

As described above, in nitride semiconductor device 101 according to the present embodiment, the off breakdown voltage can be improved while gate-drain parasitic capacitance Cgd is reduced. Thus, nitride semiconductor device 101 that operates at a high speed and has high reliability at the same time can be implemented.

### Embodiment 3

Now, Embodiment 3 will be described.

In Embodiment 3, the size of p-type semiconductor layer disposed immediately below the second source electrode is different from that in Embodiment 1. Hereinafter, differences from Embodiment 1 will be mainly described, and the descriptions of shared features will be omitted or simplified.

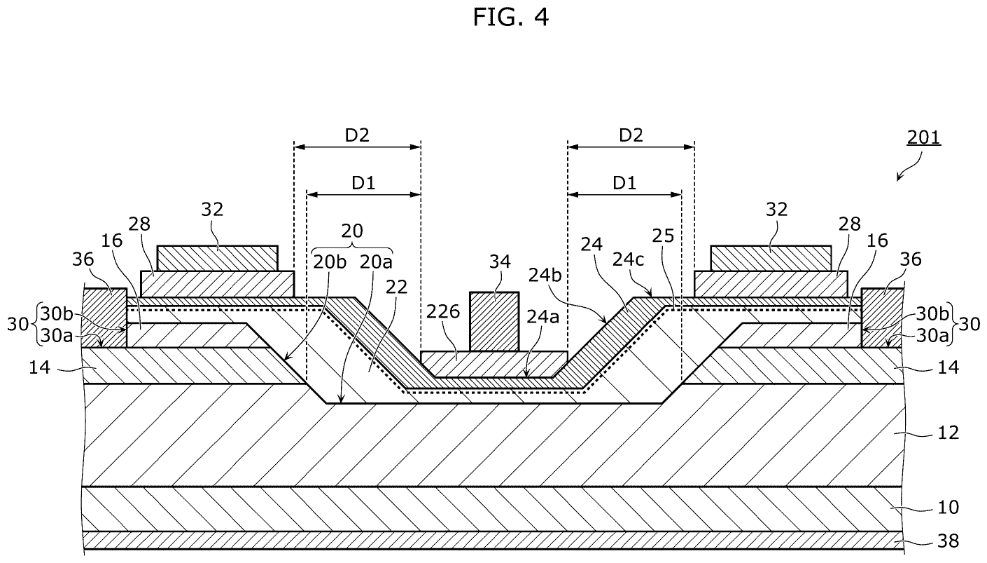

FIG. 4 is a cross-sectional view of nitride semiconductor device 201 according to Embodiment 3. Unlike nitride semiconductor device 1 illustrated in FIG. 1, as illustrated in FIG. 4, nitride semiconductor device 201 includes p-type semiconductor layer 226 instead of p-type semiconductor layer 26. P-type semiconductor layer 226 is one example of the second p-type nitride semiconductor layer, which is different from p-type semiconductor layer 26 in the region of the upper surface of electron supply layer 24 covered by the p-type nitride semiconductor layer.

Specifically, p-type semiconductor layer 226 continuously covers flat portion 24a and part of inclined portion 24b in the upper surface of electron supply layer 24. More specifically, p-type semiconductor layer 226 continuously covers entire flat portion 24a and part of inclined portion 24b. For example, the region of inclined portion 24b covered is a region smaller than or equal to a lower half of inclined portion 24b, although not particularly limited thereto.

Such a configuration, in which p-type semiconductor layer 226 covers the upper surface of electron supply layer 24 and flat portion 24a and part of inclined portion 24b, can increase portions on which the electric field in an off state is likely to concentrate. Specifically, the electric field can be received by the end of block layer 14 on p-type semiconductor layer 226 side, the bottom surface of p-type semiconductor layer 226, and the end of p-type semiconductor layer 226. Thus, the concentration of the electric field can be relaxed, and therefor, off-leakage can be reduced. Like Embodiment 1, because p-type semiconductor layer 226 can block electric lines of force, gate-drain parasitic capacitance Cgd can be reduced, and high-speed operation of the transistor can be implemented.

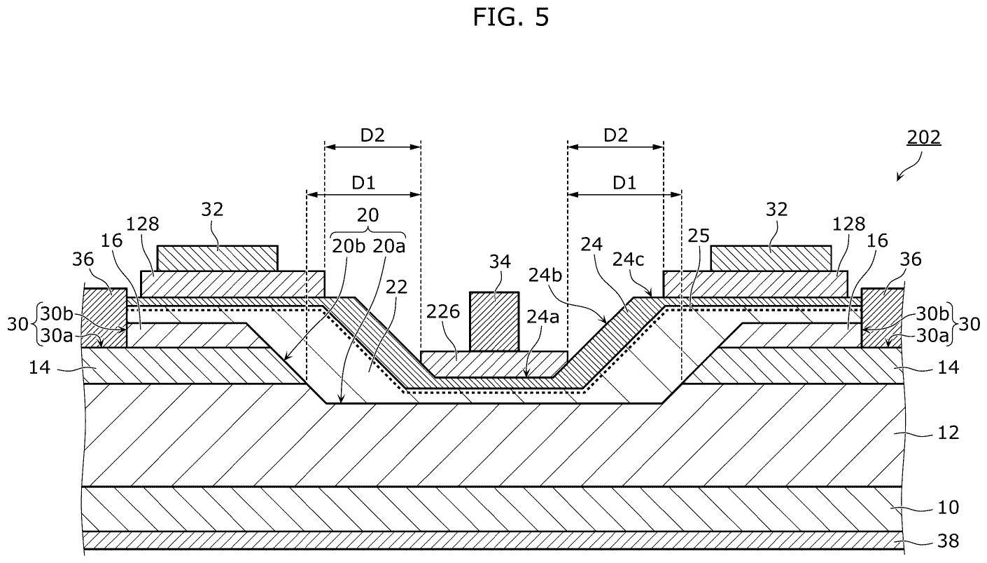

FIG. 5 is a cross-sectional view of nitride semiconductor device 202 according to a modification of Embodiment 3. Unlike nitride semiconductor device 101 illustrated in FIG. 4, as illustrated in FIG. 5, nitride semiconductor device 202 includes threshold adjustment layer 128 instead of threshold adjustment layer 28. Threshold adjustment layer 128 is the same one as threshold adjustment layer 128 illustrated in FIG. 3.

Specifically, in the planar view of substrate 10, distance D2 between threshold adjustment layer 128 and p-type semiconductor layer 226 is shorter than distance D1 between block layer 14 and p-type semiconductor layer 226. In other words, the end of threshold adjustment layer 128 on p-type semiconductor layer 226 side is located closer to p-type semiconductor layer 226 than the end of block layer 14 on p-type semiconductor layer 226.

Thereby, a reduction in off-leakage by relaxing the concentration of the electric field and an increase in breakdown voltage by increasing the length of the gate can be satisfied at the same time. Since p-type semiconductor layer 226 can block the electric lines of force, gate-drain parasitic capacitance Cgd can be reduced, and high-speed operation of the transistor can be implemented.

### Embodiment 4

Now, Embodiment 4 will be described.

In Embodiment 4, unlike Embodiment 1, the bottom portion of the p-type semiconductor layer disposed immediately below the second source electrode is closer to the drain electrode than the bottom portion of the block layer is. Hereinafter, differences from Embodiment 1 will be mainly described, and the descriptions of shared features will be omitted or simplified.

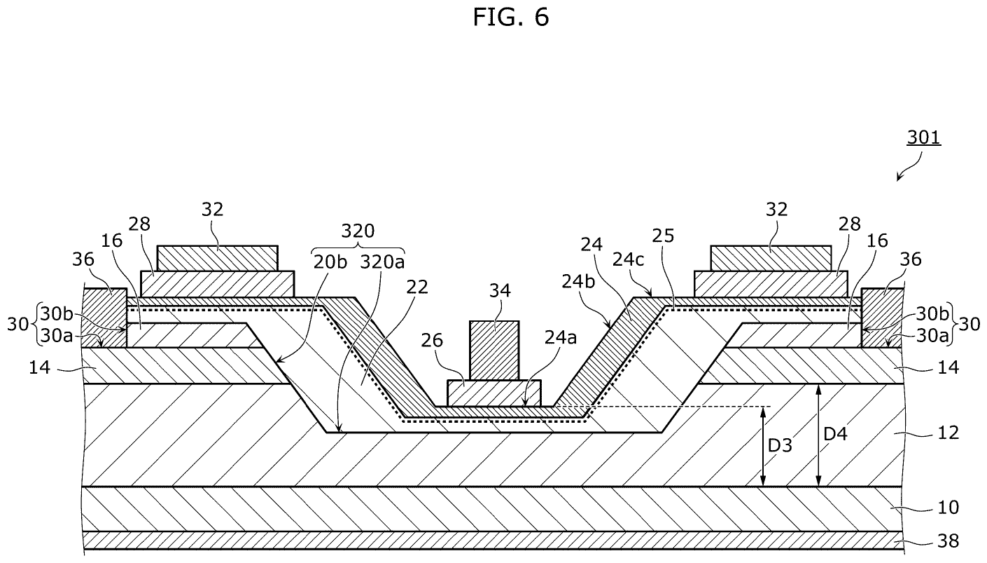

FIG. 6 is a cross-sectional view of nitride semiconductor device 301 according to the present embodiment. Unlike nitride semiconductor device 1 illustrated in FIG. 1, as illustrated in FIG. 6, nitride semiconductor device 301 includes vertical conduction opening 320 instead of vertical conduction opening 20. Unlike vertical conduction opening 20, bottom surface 320a of electrical conduction opening 320 is closer to drain electrode 38.

Specifically, bottom surface 320a of vertical conduction opening 320 is located in a deep position of drift layer 12. Specifically, bottom surface 320a of vertical conduction opening 320 is disposed such that the distance to the interface between drift layer 12 and block layer 14 in a direction intersecting perpendicular to the main surface of substrate 10 is longer than the total thickness of the thickness of electron transport layer 22 and that of electron supply layer 24.

For this reason, the bottom surface of p-type semiconductor layer 26 that covers flat portion 24a of the upper surface of electron supply layer 24 is located in a position lower than the interface between drift layer 12 and block layer 14. In other words, distance D3 between p-type semiconductor layer 26 and drain electrode 38 is shorter than distance D4 between block layer 14 and drain electrode 38.

Such a configuration can relax the concentration of the electric field in an off state by p-type semiconductor layer 26, and thus can reduce off-leakage. Since p-type semiconductor layer 26 can block electric lines of force, gate-drain parasitic capacitance Cgd can be reduced, and high-speed operation of the transistor can be implemented.

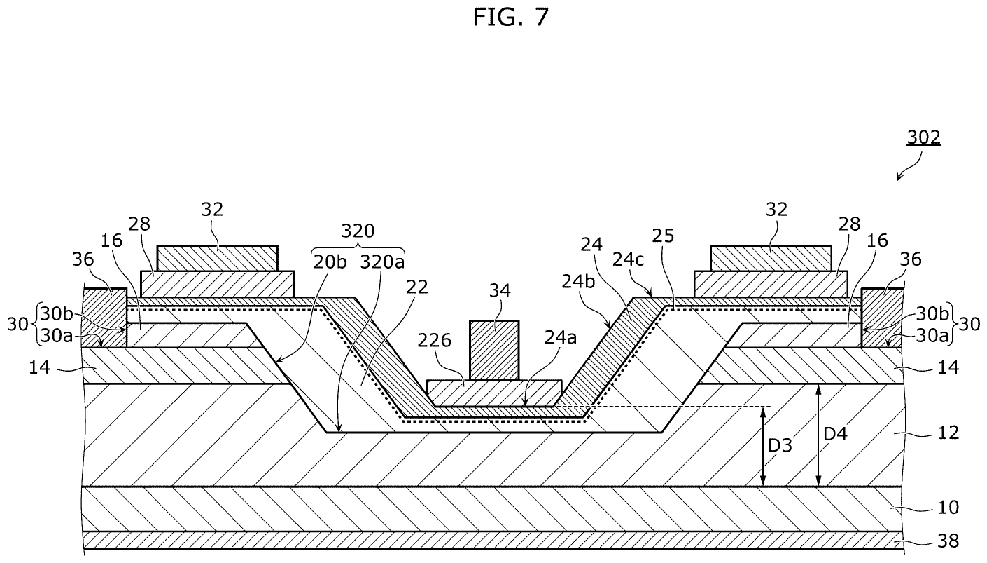

FIG. 7 is a cross-sectional view of nitride semiconductor device 302 according to a modification of Embodiment 4. Unlike nitride semiconductor device 301 illustrated in FIG. 6, as illustrated in FIG. 7, nitride semiconductor device 302 includes p-type semiconductor layer 226 instead of p-type semiconductor layer 26. P-type semiconductor layer 226 is the same one as p-type semiconductor layer 226 illustrated in FIG. 4.

Specifically, p-type semiconductor layer 226 continuously covers flat portion 24a and part of inclined portion 24b in the upper surface of electron supply layer 24. More specifically, p-type semiconductor layer 226 continuously covers entire flat portion 24a and part of inclined portion 24b.

Thereby, p-type semiconductor layer 226 can relax the concentration of the electric field in an off state, and thus off-leakage can be reduced. Since p-type semiconductor layer 226 can block electric lines of force, gate-drain parasitic capacitance Cgd can be reduced, and high-speed operation of the transistor can be implemented.

To be noted, nitride semiconductor device 301 or 302 may include threshold adjustment layer 128 instead of threshold adjustment layer 28. Thereby, off breakdown voltage can be improved while gate-drain parasitic capacitance Cgd is reduced. Thus, nitride semiconductor device 301 or 302 satisfying high-speed operation and high reliability at the same time can be implemented.

### Embodiment 5

Now, Embodiment 5 will be described.

Unlike Embodiment 1, in Embodiment 5, the lower surface of p-type semiconductor layer disposed in the vertical conduction opening is located in a position higher than that of the opening surface of the vertical conduction opening. Hereinafter, differences from Embodiment 1 will be mainly described, and the descriptions of shared features will be omitted or simplified.

### [Configuration]

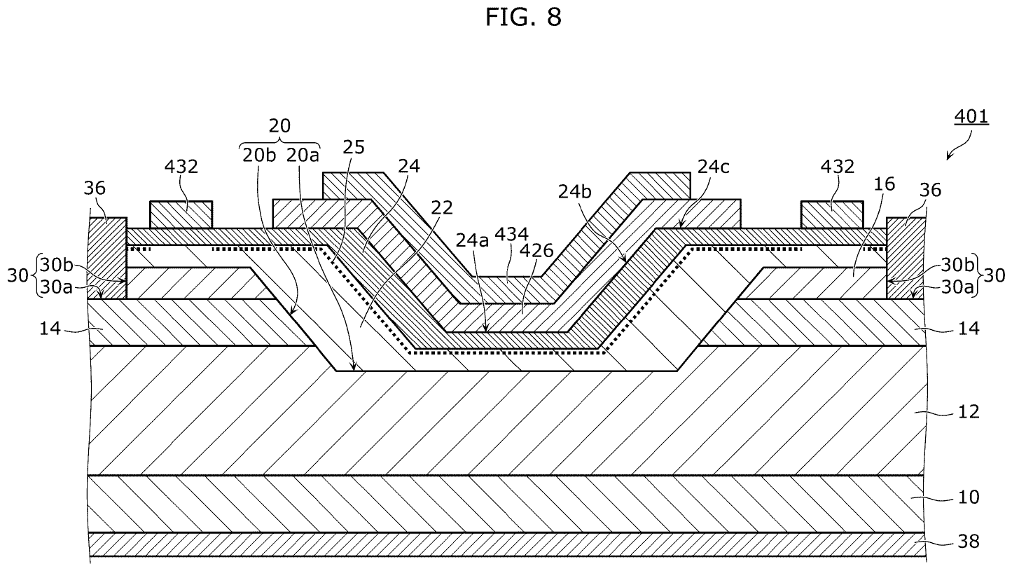

First, the configuration of the nitride semiconductor device according to Embodiment 5 will be described with reference to FIG. 8.

FIG. 8 is a cross-sectional view of nitride semiconductor device 401 according to the present embodiment. In FIG. 8, the components such as semiconductor layers and electrodes are hatched, which indicates cross-sectional views.

Nitride semiconductor device 401 according to the present embodiment is a normally-on FET, for example. In nitride semiconductor device 401, for example, first source electrode 36 is grounded (namely, the potential is 0 V), and a positive potential is given to drain electrode 38. The potential given to drain electrode 38 is 100 V or more and 1200 V or less, for example, but not limited thereto. When nitride semiconductor device 401 is in an off state, a negative potential (for example, −5 V) is applied to gate electrode 432. When nitride semiconductor device 401 is in an on state, 0 V or a positive potential (for example, +5 V) is applied to gate electrode 432. Nitride semiconductor device 401 may be a normally-off FET.

FIG. 8 illustrates the state where nitride semiconductor device 401 is in an off state, that is, a gate voltage less than the threshold voltage is applied to gate electrode 432. In this case, FIG. 8 illustrates the state where two-dimensional electron gas 25 disappears and depletion occurs immediately below gate electrode 432. When nitride semiconductor device 401 is an on state, that is, a voltage higher than or equal to the threshold voltage is applied to gate electrode 432, the potential is reduced and two-dimensional electron gas 25 generates immediately below gate electrode 432. Thereby, first source electrode 36 and drain electrode 38 are electrically conducted.

As illustrated in FIG. 8, nitride semiconductor device 401 includes substrate 10, drift layer 12, block layer 14, underlying layer 16, vertical conduction opening 20, electron transport layer 22, electron supply layer 24, p-type semiconductor layer 426, source opening 30, gate electrode 432, second source electrode 434, first source electrode 36, and drain electrode 38. Two-dimensional electron gas (2DEG) 25 that functions as the channel generates at the interface between electron transport layer 22 and electron supply layer 24. In other words, unlike nitride semiconductor device 1 according to Embodiment 1, nitride semiconductor device 401 includes p-type semiconductor layer 426, gate electrode 432, and second source electrode 434 instead of p-type semiconductor layer 26, gate electrode 32, and second source electrode 34. Nitride semiconductor device 401 does not include threshold adjustment layer 28. Hereinafter, detailed configurations of p-type semiconductor layer 426, gate electrode 432, and second source electrode 434 will be mainly described.

P-type semiconductor layer 426 is one example of the second p-type nitride semiconductor layer, and is disposed above electron supply layer 24 in a position overlapping with bottom surface 20a and lateral surface 20b of vertical conduction opening 20 in the planar view of substrate 10. Part of the lower surface of p-type semiconductor layer 426 is located in a position higher than that of the opening surface of vertical conduction opening 20. Specifically, the lower surface of p-type semiconductor layer 426 continuously covers at least part of flat portion 24a, inclined portion 24b, and part of outer edge portion 24c in the upper surface of electron supply layer 24. More specifically, in the cross-section illustrated in FIG. 8, the lower surface of p-type semiconductor layer 426 is disposed to be in contact with and completely cover inclined portion 24b on left, flat portion 24a, and inclined portion 24b on right from one (e.g., left) outer edge portion 24c to the other (e.g., right) outer edge portion 24c.

For example, p-type semiconductor layer 426 is a p-type AlₓGa₁₋ₓN (where 0≤x≤1) film with a thickness of 200 nm and a carrier concentration of 1×10¹⁷ cm⁻³. The thickness and carrier concentration are only exemplary, and can be appropriately changed.

P-type semiconductor layer 426 is disposed in a position away from gate electrode 432. Specifically, p-type semiconductor layer 426 is electrically separated from gate electrode 432. In the present embodiment, in the planar view of substrate 10, p-type semiconductor layer 426 overlaps with block layer 14. Specifically, in the planar view, the end of p-type semiconductor layer 426 on gate electrode 432 side (hereinafter, referred to as gate-side end) overlaps with block layer 14. In the planar view, the gate-side end of p-type semiconductor layer 426 may overlap with the upper surface of block layer 14. Alternatively, in the planar view, the gate-side end of p-type semiconductor layer 426 may overlap with the inclined lateral surface of block layer 14 (namely, lateral surface 20b of vertical conduction opening 20). Alternatively, in the planar view, the gate-side end of p-type semiconductor layer 426 may overlap with the upper surface of underlying layer 16. In other words, in the planar view, the gate-side end of p-type semiconductor layer 426 may be located in a position closer to gate electrode 432 and first source electrode 36 than the upper edge of lateral surface 20b of vertical conduction opening 20 is. Simply stated, in the planar view, the gate-side end of p-type semiconductor layer 426 may be located outside vertical conduction opening 20. As the gate-side end of p-type semiconductor layer 426 becomes closer to gate electrode 432, that is, p-type semiconductor layer 426 becomes larger, a higher effect of blocking electric lines of force described later can be obtained, resulting in a further contribution to a reduction in parasitic capacitance Cgd.

Instead of p-type semiconductor layer 426, an insulating layer having a monolayer or multilayer structure including a film of a compound selected from the group consisting of SiN, SiO₂, HfO₂, Al₂O₃, ZrO₂, AlN, HfON, and ZrON may be disposed.

Electron transport layer 22, electron supply layer 24, and p-type semiconductor layer 426 are formed by forming vertical conduction opening 20, and then continuously forming nitride semiconductor films through a crystal regrowth step, followed by patterning in a predetermined shape. Specifically, the undoped GaN film as the base for electron transport layer 22, the undoped AlGaN film as the base for electron supply layer 24, and the p-type AlGaN film as the base for p-type semiconductor layer 426 are continuously formed by MOVPE or HVPE. After the film formation, by removing part of the p-type AlGaN film by etching until the undoped AlGaN film is exposed, p-type semiconductor layer 426 is formed. Furthermore, part of the undoped AlGaN film, part of the undoped GaN film, and part of underlying layer 16 are continuously removed by etching until block layer 14 is exposed. Thereby, source opening 30 that reaches block layer 14 is formed, and electron supply layer 24 and electron transport layer 22 patterned in a predetermined shape are formed.

Gate electrode 432 is disposed above electron supply layer 24 in a position overlapping with underlying layer 16 in the planar view of substrate 10. Specifically, gate electrode 432 is disposed in contact with the upper surface of electron supply layer 24. More specifically, gate electrode 432 is disposed in contact with outer edge portion 24c of the upper surface of electron supply layer 24.

Gate electrode 432 is formed, for example, using a conductive material such as a metal. For example, for gate electrode 432, a material to be in Schottky contact with an n-type GaN layer can be used. For example, a palladium (Pd) material, a nickel (Ni) material, tungsten silicide (WSi), or gold (Au) can be used. Gate electrode 432 is formed by forming source opening 30 or forming first source electrode 36 and second source electrode 434, then forming a conductive film by sputtering or deposition, and patterning the obtained conductive film.

Second source electrode 434 is disposed above p-type semiconductor layer 426 to cover vertical conduction opening 20 in the planar view. Specifically, second source electrode 434 is disposed in contact with the upper surface of p-type semiconductor layer 426.

Like p-type semiconductor layer 426, second source electrode 434 is disposed above electron supply layer 24 in a position overlapping with bottom surface 20a and lateral surface 20b of vertical conduction opening 20 in the planar view of substrate 10. Part of the lower surface of second source electrode 434 is located in a position higher than that of the opening surface of vertical conduction opening 20. In the planar view of substrate 10, second source electrode 434 overlaps with flat portion 24a, inclined portion 24b, and outer edge portion 24c of the upper surface of electron supply layer 24. In other words, in the planar view, the gate-side end of second source electrode 434 overlaps with outer edge portion 24c of the upper surface of electron supply layer 24.

In the planar view, the gate-side end of second source electrode 434 may overlap with block layer 14. In the planar view, the gate-side end of second source electrode 434 may overlap with the upper surface of block layer 14. Alternatively, in the planar view, the gate-side end of p-type semiconductor layer 426 may overlap with the inclined lateral surface of block layer 14 (namely, lateral surface 20b of vertical conduction opening 20). In the planar view, the gate-side end of second source electrode 434 may overlap with the upper surface of underlying layer 16. In other words, in the planar view, the gate-side end of second source electrode 434 may be located in a position closer to gate electrode 432 and first source electrode 36 than the upper edge of lateral surface 20b of vertical conduction opening 20 is. Simply stated, in the planar view, the gate-side end of second source electrode 434 may be located outside vertical conduction opening 20. As the gate-side end of second source electrode 434 becomes closer to gate electrode 432, that is, second source electrode 434 becomes larger, a higher effect of blocking electric lines of force described later can be obtained, resulting in a further contribution to a reduction in parasitic capacitance Cgd.

Second source electrode 434 is electrically connected to first source electrode 36. In other words, second source electrode 434 is an electrode to which the same source potential as that to first source electrode 36 is fed. Second source electrode 434 is not directly connected to two-dimensional electron gas 25. The drain current from drain electrode 38 flows through two-dimensional electron gas 25 to first source electrode 36. Second source electrode 434 is electrically connected to p-type semiconductor layer 426. For this reason, as in block layer 14, a source potential is applied to p-type semiconductor layer 426.

Second source electrode 434 is formed using a conductive material such as a metal. Second source electrode 434 can be formed using the same material as that for gate electrode 432. For this reason, second source electrode 434 and gate electrode 432 can be formed through the same step, for example. Second source electrode 434 is formed, for example, by forming a conductive film by sputtering or deposition, and patterning the obtained conductive film.

### [Characteristic Configuration]

Now, the main and characteristic configuration of nitride semiconductor device 401 according to the present embodiment will be described.

As described above, in nitride semiconductor device 401 according to the present embodiment, p-type semiconductor layer 426 and second source electrode 434 are disposed in a position higher than that of the opening surface of vertical conduction opening 20 to cover lateral surface 20b and bottom surface 20a of vertical conduction opening 20. Moreover, gate electrode 432 is disposed above electron supply layer 24 to be electrically independent from first source electrode 36 and second source electrode 434. Specifically, gate electrode 432 is disposed away from first source electrode 36, second source electrode 434, and p-type semiconductor layer 426.

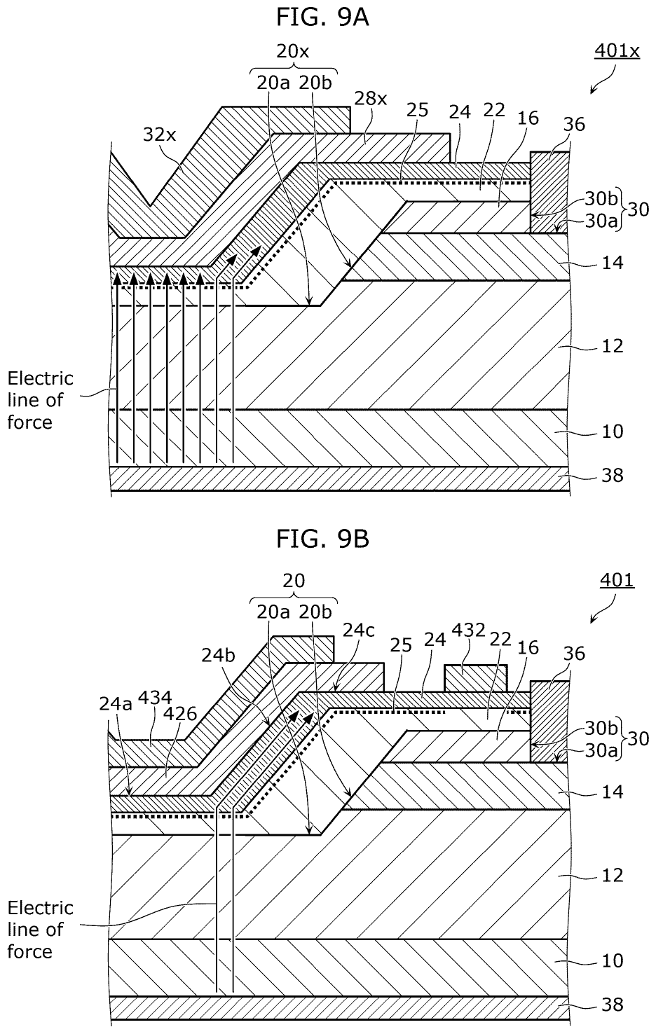

Hereinafter, with reference to FIGS. 9A and 9B, nitride semiconductor device 401 according to the present embodiment will be specifically described in comparison to that in Comparative Example. FIGS. 9A and 9B are diagrams for illustrating gate-drain parasitic capacitance Cgd in the nitride semiconductor device according to Comparative Example and that in the nitride semiconductor device according to the present embodiment.

FIG. 9A illustrates a portion near gate opening 20x in a cross-sectional configuration of nitride semiconductor device 401x according to Comparative Example. Compared to nitride semiconductor device 401, nitride semiconductor device 401x according to Comparative Example includes gate opening 20x, gate electrode 32x, and threshold adjustment layer 28x instead of vertical conduction opening 20, p-type semiconductor layer 426, gate electrode 432, and second source electrode 434.

Gate opening 20x is substantially the same as vertical conduction opening 20. Gate electrode 32x and threshold adjustment layer 28x are arranged along bottom surface 20a and lateral surface 20b of gate opening 20x. Specifically, threshold adjustment layer 28x is disposed to cover flat portion 24a, inclined portion 24b, and outer edge portion 24c of the upper surface of electron supply layer 24. Gate electrode 32x is also disposed in contact with the upper surface of threshold adjustment layer 28x. Specifically, gate electrode 32x is disposed in a position overlapping with bottom surface 20a of gate opening 20x in the planar view.

In such a configuration, the area of a portion in which gate electrode 32x and threshold adjustment layer 28x face drain electrode 38 is increased. This results in a large parallel plate capacitance between the gate and the drain, and thus, substantially all the electric lines of force from the drain toward the gate that contribute to gate-drain parasitic capacitance Cgd are terminated in the gate. For this reason, parasitic capacitance Cgd is difficult to reduce.

On the other hand, in the configuration according to the present embodiment, as illustrated in FIG. 9B, second source electrode 434 and p-type semiconductor layer 426 are arranged near bottom surface 20a of vertical conduction opening 20. For this reason, part of electric lines of force from the drain toward the gate can be terminated in second source electrode 434 and p-type semiconductor layer 426. As a result, gate-drain parasitic capacitance Cgd can be reduced.

As illustrated in FIG. 9B, block layer 14 is also disposed between gate electrode 432 and drain electrode 38. Thereby, block layer 14 can also block electric lines of force to gate electrode 432. For this reason, gate-drain parasitic capacitance Cgd can be further reduced, and high-speed operation of the transistor can be implemented.

Second source electrode 434 is in contact with p-type semiconductor layer 426, and a pn diode is formed by p-type semiconductor layer 426 and two-dimensional electron gas 25. Thereby, compared to that of a Schottky diode, leakage current in the reverse direction can be further reduced and the breakdown voltage can be improved. Thus, a transistor having high reliability can be implemented.

### [Modification]

Now, a modification of Embodiment 5 will be described.

As the main difference from Embodiment 5, in the modification of Embodiment 5, an opening is disposed in the p-type nitride semiconductor layer disposed above the electron supply layer, and the second source electrode is connected to the electron supply layer through the opening. Hereinafter, differences from Embodiment 5 will be mainly described, and the descriptions of shared features will be omitted or simplified.

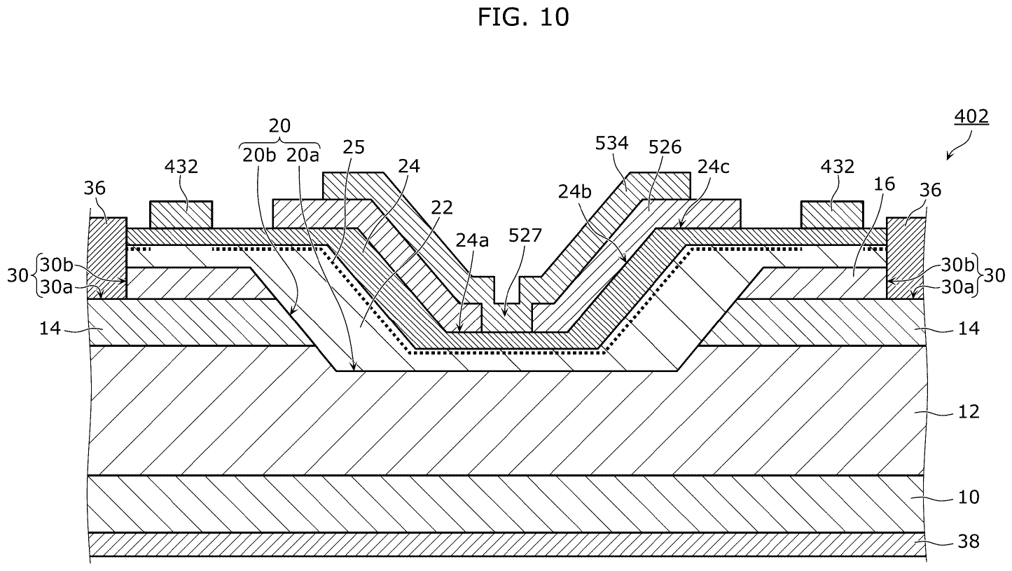

FIG. 10 is a cross-sectional view of nitride semiconductor device 402 according to modification 1 of Embodiment 5. Unlike nitride semiconductor device 401, as illustrated in FIG. 10, nitride semiconductor device 402 includes p-type semiconductor layer 526 and second source electrode 534 instead of p-type semiconductor layer 426 and second source electrode 434.

As differences from Embodiment 5, p-type semiconductor layer 526 corresponds to p-type semiconductor layer 426, and opening 527 is disposed. Opening 527 is one example of the third opening, and penetrates through p-type semiconductor layer 526 and reaches electron supply layer 24. In the planar view of substrate 10, opening 527 is disposed in a position overlapping with flat portion 24a of the upper surface of electron supply layer 24.

Second source electrode 534 is disposed to cover opening 527. As differences, specifically, second source electrode 534 corresponds to second source electrode 434, and is in contact with electron supply layer 24 in the bottom surface of opening 527. To be noted, any number of openings 527 of any size and shape can be arranged as long as second source electrode 534 is enabled to be contact with electron supply layer 24.

For second source electrode 534, an electrode material to be in a Schottky contact with n-type GaN is used. Since two-dimensional electron gas 25 that generates near the interface of the heterojunction between electron supply layer 24 and electron transport layer 22 can be regarded as n-type GaN, second source electrode 534 of opening 527 is in Schottky contact with electron supply layer 24. This results in a junction barrier Schottky (JBS) structure near vertical conduction opening 20, the structure including a pn diode configured with p-type semiconductor layer 526 and two-dimensional electron gas 25 and a Schottky diode configured with second source electrode 534 and electron supply layer 24. The threshold voltage of the JBS structure is lower than that of the pn diode.

When nitride semiconductor device 402 operates in a reverse conducting mode, a current flows in the JBS structure near vertical conduction opening 20. At this time, the threshold voltage is reduced, and thus the drive voltage is reduced, resulting in a reduction in conduction loss in the reverse conducting mode.

In the planar view of substrate 10, opening 527 disposed in p-type semiconductor layer 526 is disposed in a position overlapping with bottom surface 20a of vertical conduction opening 20, although any other configuration can be used. In the planar view of substrate 10, opening 527 may overlap with lateral surface 20b of vertical conduction opening 20, or may be disposed in a position not overlapping with vertical conduction opening 20. In other words, inclined portion 24b or outer edge portion 24c in the upper surface of electron supply layer 24 may be exposed from the bottom surface of opening 527.

### Embodiment 6

Now, Embodiment 6 will be described.

As the main difference from Embodiment 5, in Embodiment 6, the threshold adjustment layer is disposed between the gate electrode and the electron supply layer. Hereinafter, differences from Embodiment 5 will be mainly described, and the descriptions of shared features will be omitted or simplified.

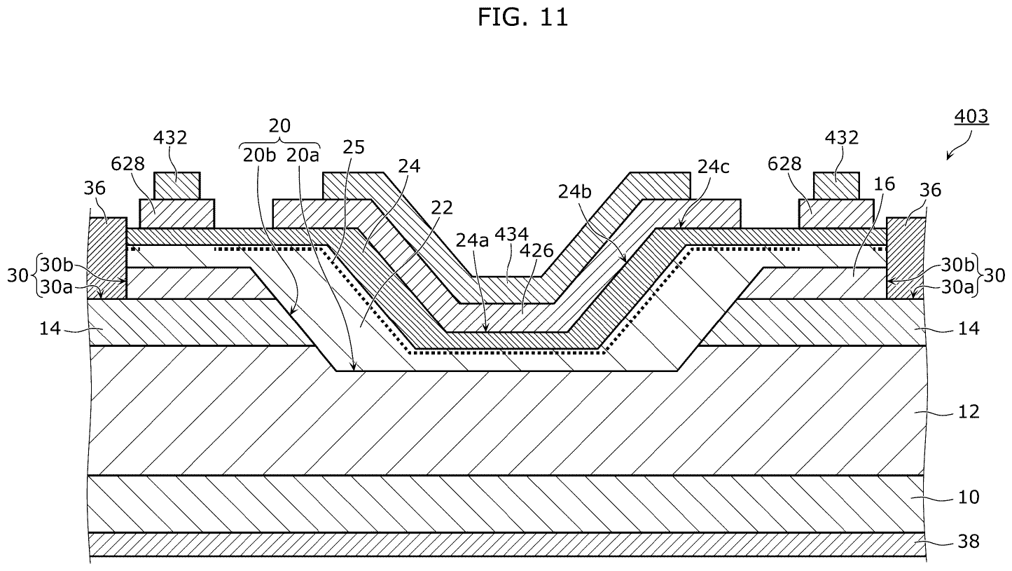

FIG. 11 is a cross-sectional view nitride semiconductor device 403 according to Embodiment 6. Unlike nitride semiconductor device 401 illustrated in FIG. 8, as illustrated in FIG. 11, nitride semiconductor device 403 includes threshold adjustment layer 628.

Threshold adjustment layer 628 is one example of the third p-type nitride semiconductor layer, and is disposed between gate electrode 432 and electron supply layer 24 to be spaced from p-type semiconductor layer 426. Specifically, in the planar view, threshold adjustment layer 628 is disposed in a position overlapping with underlying layer 16 to be in direct contact with the upper surface of electron supply layer 24. Gate electrode 432 is disposed above threshold adjustment layer 628. Gate electrode 432 is in contact with the upper surface of threshold adjustment layer 628.

Threshold adjustment layer 628 and p-type semiconductor layer 426 are spaced from each other, and are electrically separated from each other. Threshold adjustment layer 628 and first source electrode 36 are spaced from each other, and are electrically separated from each other.

For example, threshold adjustment layer 628 is a p-type AlₓGa₁₋ₓN (where 0≤x≤1) film with a thickness of 200 nm and a carrier concentration of 1×10¹⁷ cm⁻³. For example, the composition, the thickness and carrier concentration of threshold adjustment layer 628 are the same as those of p-type semiconductor layer 426. The thickness and the carrier concentration are only exemplary, and can be appropriately changed.

In this configuration, the carrier concentration immediately below gate electrode 432 can be reduced, and the threshold voltage of the transistor can be shifted to the positive side. For this reason, nitride semiconductor device 403 according to this aspect can be easily implemented as a normally-off FET.

Threshold adjustment layer 628 can be simultaneously formed with p-type semiconductor layer 426 below second source electrode 434. Specifically, electron transport layer 22, electron supply layer 24, p-type semiconductor layer 426, and threshold adjustment layer 628 are formed by forming vertical conduction opening 20, and then continuously forming nitride semiconductor films through a crystal regrowth step, followed by patterning in a predetermined shape. Specifically, an undoped GaN film as the base for electron transport layer 22, an undoped AlGaN film as the base for electron supply layer 24, and a p-type AlGaN film as the base for p-type semiconductor layer 426 and threshold adjustment layer 628 are continuously formed by MOVPE or HVPE. After the film formation, by removing part of the p-type AlGaN film by etching until the undoped AlGaN film is exposed, p-type semiconductor layer 426 and threshold adjustment layer 628 are formed. Threshold adjustment layer 628 may be formed by a step different from the step of forming p-type semiconductor layer 426. Since threshold adjustment layer 628 can have a composition, thickness, and carrier concentration different from those of p-type semiconductor layer 426, the threshold voltage can be controlled to a desired value.

In the present embodiment, for gate electrode 432, a material to be in ohmic contact with the p-type GaN layer can be used. For example, a palladium (Pd) material, a nickel (Ni) material, tungsten silicide (WSi), or gold (Au) can be used. Gate electrode 432 is formed by forming source opening 30 or forming first source electrode 36 and second source electrode 434, forming a conductive film by sputtering or deposition, and then patterning the obtained conductive film.

In the present embodiment, as in the modification of Embodiment 5, opening 527 may be disposed in p-type semiconductor layer 426, and second source electrode 434 may be connected to electron supply layer 24 through opening 527.

### Embodiment 7

Now, Embodiment 7 will be described.

As the main difference from Embodiment 5, in Embodiment 7, an insulating film is disposed between the gate electrode and the electron supply layer. Hereinafter, differences from Embodiment 5 will be mainly described, and the descriptions of shared features will be omitted or simplified.

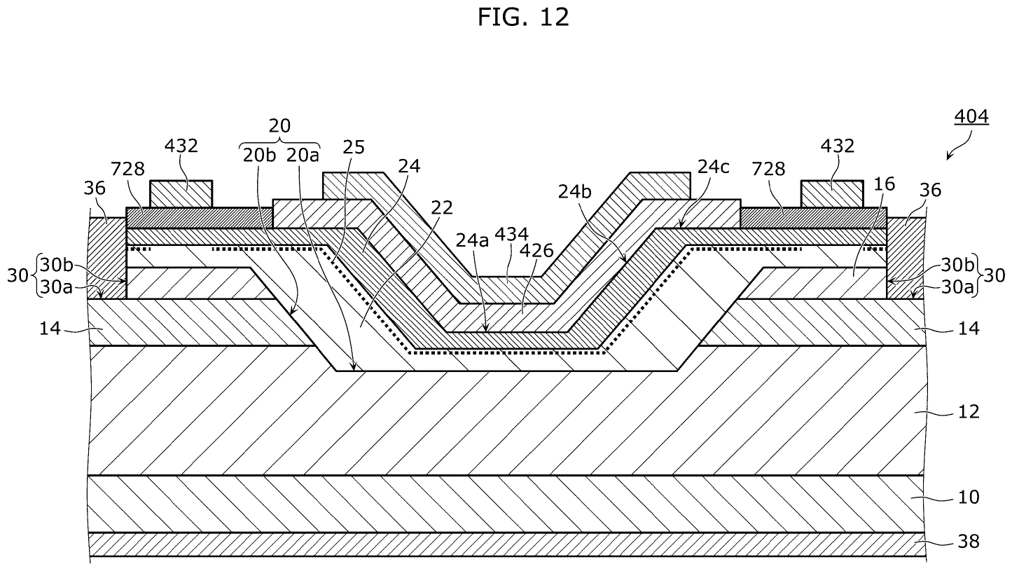

FIG. 12 is a cross-sectional view of nitride semiconductor device 404 according to Embodiment 7. Unlike nitride semiconductor device 401 illustrated in FIG. 8 as illustrated in FIG. 12, nitride semiconductor device 404 includes insulating film 728.

Insulating film 728 is disposed between gate electrode 432 and electron supply layer 24. Specifically, in the planar view, insulating film 728 is disposed in a position overlapping with underlying layer 16 to be in direct contact with the upper surface of electron supply layer 24. Gate electrode 432 is disposed above insulating film 728. Gate electrode 432 is in contact with the upper surface of insulating film 728. Gate electrode 432 and p-type semiconductor layer 426 below second source electrode 434 are spaced from each other, and are electrically separated from each other. Insulating film 728 may be in contact with p-type semiconductor layer 426 and first source electrode 36.

Insulating film 728 has a monolayer or multilayer structure including a film of a compound selected from the group consisting of SiN, SiO₂, HfO₂, Al₂O₃, ZrO₂, AlN, HfON, and ZrON. Insulating film 728 is formed by sputtering, atomic layer deposition (ALD), or plasma chemical vapor deposition (CVD) after formation of source opening 30, for example. When an insulating film is disposed below second source electrode 434 instead of p-type semiconductor layer 426, the insulating film and insulating film 728 may be simultaneously formed.

In such a configuration, the gate of nitride semiconductor device 404 has a metal-insulator-semiconductor (MIS) structure. Thus, nitride semiconductor device 404 can suppress the reverse leakage current in the gate, and is implemented as a voltage-driven device. Thus, high-speed operation and high reliability can be satisfied at the same time, and nitride semiconductor device 404 easy to drive can be implemented.

In the present embodiment, as in the modification of Embodiment 5, opening 527 may be disposed in p-type semiconductor layer 426, and second source electrode 434 may be connected to electron supply layer 24 through opening 527. Threshold adjustment layer 628 according to Embodiment 6 and insulating film 728 may be laminated. In this case, because the threshold voltage can be further shifted to the positive side, false turn-on can be suppressed, and the reliability of nitride semiconductor device 404 can be enhanced.

### Embodiment 8

Now, Embodiment 8 will be described.

As a difference from Embodiment 5, in Embodiment 8, an impurity region is disposed in part of the electron supply layer immediately below the gate electrode. Hereinafter, differences from Embodiment 5 will be mainly described, and the descriptions of shared features will be omitted or simplified.

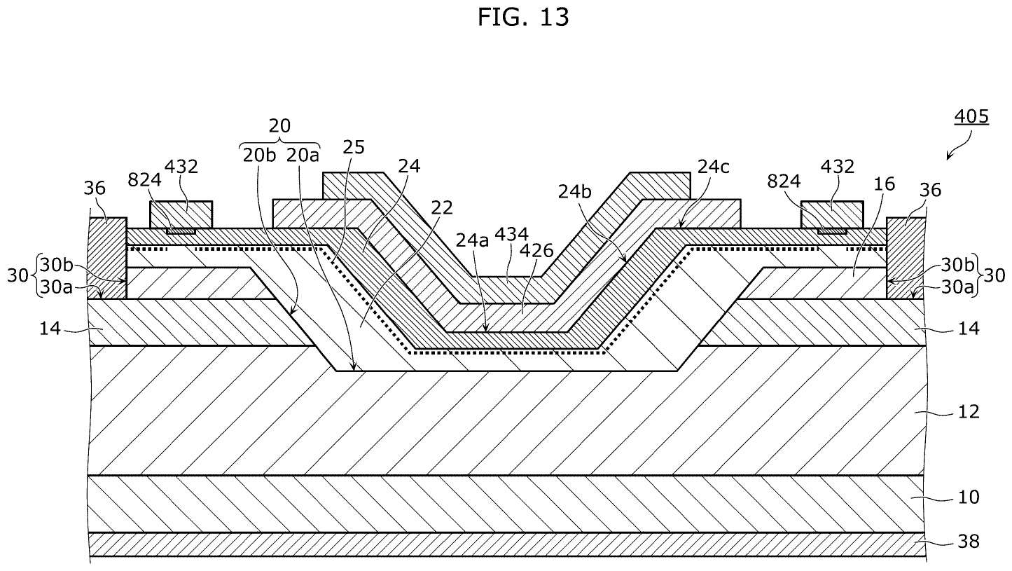

FIG. 13 is a cross-sectional view of nitride semiconductor device 405 according to Embodiment 8. As a difference from nitride semiconductor device 401 illustrated in FIG. 8, as illustrated in FIG. 13, impurity region 824 is disposed in nitride semiconductor device 405.

In the planar view of substrate 10, impurity region 824 is an impurity region disposed in a region overlapping with gate electrode 432. Specifically, in the planar view, impurity region 824 is a region that is disposed in part of electron supply layer 24 in a position overlapping with gate electrode 432 and is doped with Fe or B by ion injection to the part of electron supply layer 24, in which a defect acting as a trap of electrons is generated and high resistance is provided. Alternatively, impurity region 824 may be a region doped with a Mg that acts as an acceptor in GaN, for example. Impurity region 824 can also be called as ion injected region.

In the present embodiment, in the planar view, impurity region 824 is disposed in a region narrower than gate electrode 432. Specifically, entire impurity region 824 is covered by gate electrode 432, and gate electrode 432 is in contact with a region other than impurity region 824 in electron supply layer 24. In the planar view, impurity region 824 may be formed in a larger size than that of gate electrode 432. Part of impurity region 824 need not to be covered by gate electrode 432.

In such a configuration, the carrier concentration immediately below gate electrode 432 can be reduced, and the threshold voltage of the transistor can be shifted to the positive side. For this reason, nitride semiconductor device 405 according to this aspect can be easily implemented as a normally-off FET.

In the present embodiment, as in the modification of Embodiment 5, opening 527 may be disposed in p-type semiconductor layer 426, and second source electrode 434 may be connected to electron supply layer 24 through opening 527. At least one of threshold adjustment layer 628 according to Embodiment 6 and insulating film 728 according to Embodiment 7 may be disposed between impurity region 824 and gate electrode 432. In this case, because the threshold voltage can be further shifted to the positive side, false turn-on can be suppressed, and the reliability of nitride semiconductor device 405 can be enhanced.

### Embodiment 9

Now, Embodiment 9 will be described.

As a difference from Embodiment 5, in Embodiment 9, a depressed portion is disposed in part of the electron supply layer immediately below the gate electrode. The depressed portion is also referred to as recess. The nitride semiconductor device according to the present embodiment has a gate recess structure. Hereinafter, differences from Embodiment 5 will be mainly described, and the descriptions of shared features will be omitted or simplified.

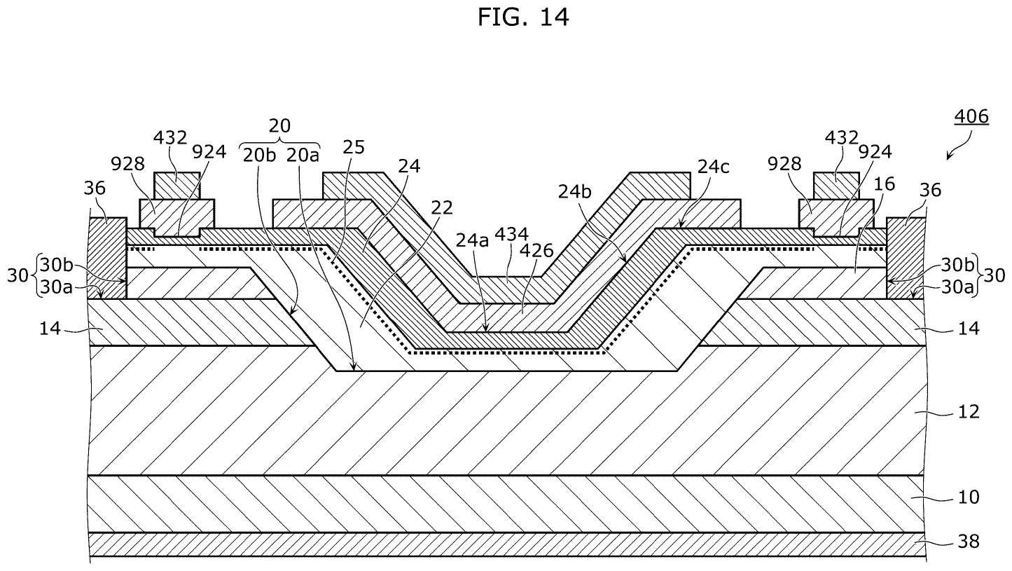

FIG. 14 is a cross-sectional view of nitride semiconductor device 406 according to Embodiment 9. As a difference from nitride semiconductor device 401 illustrated in FIG. 8, as illustrated in FIG. 14, nitride semiconductor device 406 includes a gate recess structure. Specifically, nitride semiconductor device 406 includes threshold adjustment layer 928. Depressed portion 924 is disposed in electron supply layer 24.

In the planar view of substrate 10, depressed portion 924 is disposed in a position overlapping with gate electrode 432. Depressed portion 924 is formed by removing part of electron supply layer 24 by dry etching, for example.

As a difference, threshold adjustment layer 928 corresponds to threshold adjustment layer 628 according to Embodiment 6, and is disposed to cover depressed portion 924. Threshold adjustment layer 928 is in contact with the bottom surface and the lateral surface of depressed portion 924 and covers these surfaces. Threshold adjustment layer 928 is not disposed, and gate electrode 432 may be in contact with the bottom surface and lateral surface of depressed portion 924. Alternatively, the same insulating film as insulating film 728 may be disposed instead of threshold adjustment layer 928.

In the present embodiment, in the planar view, depressed portion 924 is disposed in a region narrower than threshold adjustment layer 928. Specifically, entire depressed portion 924 is covered by threshold adjustment layer 928, and threshold adjustment layer 928 is also in contact with the outer region of depressed portion 924 in electron supply layer 24. In the planar view, depressed portion 924 may be formed smaller than threshold adjustment layer 928 and gate electrode 432. For example, threshold adjustment layer 928 and gate electrode 432 may cover the bottom surface of depressed portion 924, and need not cover the lateral surface of depressed portion 924.

In such a configuration, the carrier concentration immediately below gate electrode 432 can be reduced, and the threshold voltage of the transistor can be further shifted to the positive side. For this reason, nitride semiconductor device 406 according to this aspect can be most easily implemented as a normally-off FET.

Alternatively, instead of disposing depressed portion 924, the thickness of electron supply layer 24 may be increased in a direction different from that immediately below threshold adjustment layer 928 and gate electrode 432. Alternatively, the Al composition in electron supply layer 24 may be increased. Thereby, on-resistance can be reduced while the threshold voltage equal to that of nitride semiconductor device 401 is achieved.

Depressed portion 924 is formed by continuously forming nitride semiconductor films, i.e., electron transport layer 22 and electron supply layer 24 through a crystal regrowth step, followed by patterning in a predetermined shape. Specifically, an undoped GaN film as the base for electron transport layer 22 and an undoped AlGaN film as the base for electron supply layer 24 are continuously formed by MOVPE or HVPE. After the film formation, by removing part of the undoped AlGaN film by etching, depressed portion 924 is formed. Thereafter, a p-type AlGaN layer as the base for threshold adjustment layer 928 and p-type semiconductor layer 426 is formed by MOVPE or HVPE. After the film formation, by removing part of the p-type AlGaN film by etching, threshold adjustment layer 928 and p-type semiconductor layer 426 are formed to be separated from each other. In other words, nitride semiconductor device 406 can be manufactured by adding one more regrowth step to the conventional regrowth step.

Although the bottom portion of depressed portion 924 is disposed above the upper surface of electron transport layer 22, depressed portion 924 may penetrate through electron supply layer 24 and reach electron transport layer 22. In this case, the same structure as above can be formed by again forming an undoped AlGaN film and a p-type AlGaN film by a subsequent crystal growth step.

In the present embodiment, as in the modification of Embodiment 5, opening 527 may be disposed in p-type semiconductor layer 426, and second source electrode 434 may be connected to electron supply layer 24 through opening 527. Insulating film 728 according to Embodiment 7 may be laminated on threshold adjustment layer 928. Impurity region 824 according to Embodiment 8 may be disposed in a region of electron supply layer 24 including the bottom surface of depressed portion 924. In these cases, because the threshold voltage can be shifted to the positive side, false turn-on can be suppressed, and the reliability of nitride semiconductor device 406 can be enhanced.

### Embodiment 10

Now, Embodiment 10 will be described.

Unlike Embodiment 9, in Embodiment 10, the distance between the lower surface of the p-type semiconductor layer and the substrate is shorter than the distance between the lower surface of the block layer and the substrate. Hereinafter, differences from Embodiment 9 will be mainly described, and the descriptions of shared features will be omitted or simplified.

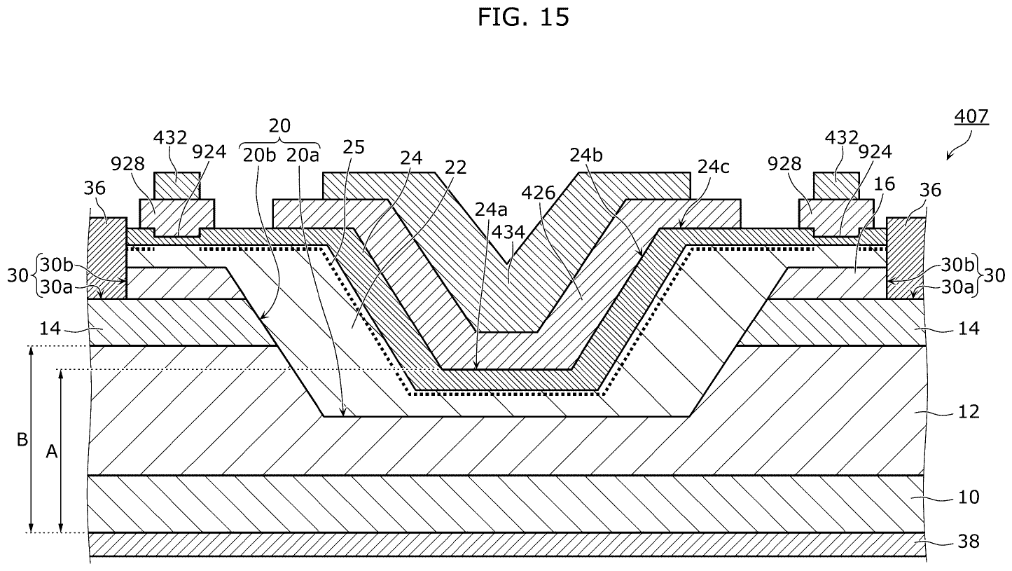

FIG. 15 is a cross-sectional view of nitride semiconductor device 407 according to Embodiment 10. As a difference from nitride semiconductor device 406 according to Embodiment 9, as illustrated in FIG. 15, nitride semiconductor device 407 includes vertical conduction opening 20 formed deeper in drift layer 12 by removing drift layer 12. Thereby, the lower surface of p-type semiconductor layer 426 is located in a position lower than the lower surface of block layer 14. Specifically, distance A between p-type semiconductor layer 426 and drain electrode 38 is shorter than distance B between block layer 14 and drain electrode 38. Distance A between p-type semiconductor layer 426 and drain electrode 38 is the shortest distance. Distance A corresponds to the distance between flat portion 24a of the upper surface of electron supply layer 24 and the upper surface of drain electrode 38.

In such a configuration, because vertical conduction opening 20 is formed by dry etching, the lateral surface of block layer 14 corresponding to lateral surface 20b of vertical conduction opening 20 includes damage by dry etching. Since the lateral surface of block layer 14 is inclined, a portion near the lateral surface of block layer 14 has a small film thickness and a sharp angle. This results in a structure in which the electric field is likely to concentrate and dielectric breakdown is likely to occur.

In contrast, in nitride semiconductor device 407, when a high voltage is applied to drain electrode 38 in an off state, a high electric field is applied to the bottom portion of p-type semiconductor layer 426 with a distance closer to drain electrode 38 than that of block layer 14 to drain electrode 38. In other words, the electric field applied to the lateral surface of block layer 14 can be relaxed. For this reason, nitride semiconductor device 407 according to this aspect can be implemented as a high breakdown voltage FET.

The relation between distance A and distance B according to the present embodiment can be applied to nitride semiconductor devices 401, 402, 403, 404, 405, and 406 according to Embodiments 5 to 10 and their modifications.

### Other Embodiments

As described above, the nitride semiconductor devices according to one or a plurality of aspects have been described based on the embodiments, but the present disclosure is not limited to these embodiments. The present disclosure also covers a variety of modifications of the present embodiments conceived and made by persons skilled in the art and embodiments configured with any combination of components in different embodiments without departing from the gist of the present disclosure.

For example, drift layer 12 may have a graded structure in which the impurity concentration (donor concentration) is gradually decreased from substrate 10 side to block layer 14 side. The donor concentration may be controlled by Si as a donor, or may be controlled by carbon as an acceptor that compensates for Si. Alternatively, drift layer 12 may have a stacking structure of a plurality of nitride semiconductor layers with different impurity concentrations. Specifically, the drift layer includes two layers, and the layer with a lower donor concentration is disposed below the block layer, and the layer with a higher donor concentration is disposed on the substrate side. By disposing vertical conduction opening 20 that penetrates through the layer with a lower donor concentration, when the transistor is on, a current flows through vertical conduction opening 20 to the layer with a higher donor concentration, which can reduce the on-resistance. In contrast, when the transistor is off, a high electric field is held by the layer with a lower donor concentration, and thus, low on-resistance and high breakdown voltage can be satisfied at the same time.

Moreover, the above-mentioned embodiments can be subjected to a variety of modifications, replacements, additions, and omissions within the scope of CLAIMS or equivalents thereof.

### INDUSTRIAL APPLICABILITY

The nitride semiconductor devices according to the present disclosure are useful as power transistors and the like used in power supply circuits and inverter circuits for devices, for example.

1. A nitride semiconductor device comprising:
a substrate;
a first nitride semiconductor layer disposed above the substrate;
a first p-type nitride semiconductor layer disposed above the first nitride semiconductor layer;
a second nitride semiconductor layer disposed above the first p-type nitride semiconductor layer;
an electron transport layer and an electron supply layer arranged sequentially from below to cover a lateral surface and a bottom surface of a first opening and an upper surface of the second nitride semiconductor layer, the first opening penetrating through the second nitride semiconductor layer and the first p-type nitride semiconductor layer and reaching the first nitride semiconductor layer;
a second p-type nitride semiconductor layer or an insulating layer disposed above the electron supply layer in a position overlapping with the bottom surface of the first opening in the planar view of the substrate;
a gate electrode disposed above the electron supply layer in a position overlapping with the second nitride semiconductor layer in the planar view of the substrate;
a first source electrode disposed to cover a second opening and electrically connected to the first p-type nitride semiconductor layer, the second opening being disposed in a position away from the gate electrode in the planar view of the substrate and penetrating through the electron supply layer and the electron transport layer and reaching the first p-type nitride semiconductor layer;
a drain electrode disposed below the substrate; and
a second source electrode disposed above the second p-type nitride semiconductor layer or the insulating layer and electrically connected to the first source electrode.

2. The nitride semiconductor device according to claim 1,
wherein the lateral surface of the first opening is inclined relative to the bottom surface of the first opening,
an upper surface of the electron supply layer includes a flat portion along the bottom surface of the first opening and an inclined portion along the lateral surface of the first opening, and
the second p-type nitride semiconductor layer or the insulating layer continuously covers the flat portion and part of the inclined portion.

3. The nitride semiconductor device according to claim 1 further comprising:
a third p-type nitride semiconductor layer disposed between the gate electrode and the electron supply layer to be spaced from the second p-type nitride semiconductor layer or the insulating layer.

4. The nitride semiconductor device according to claim 3,
wherein in the planar view of the substrate, a distance between the first p-type nitride semiconductor layer and the second p-type nitride semiconductor layer or the insulating layer is shorter than a distance between the third p-type nitride semiconductor layer and the second p-type nitride semiconductor layer or the insulating layer.

5. The nitride semiconductor device according to claim 3,
wherein in the planar view of the substrate, a distance between the third p-type nitride semiconductor layer and the second p-type nitride semiconductor layer or the insulating layer is shorter than a distance between the first p-type nitride semiconductor layer and the second p-type nitride semiconductor layer or the insulating layer.

6. The nitride semiconductor device according to claim 1,
wherein a distance between the second p-type nitride semiconductor layer or the insulating layer and the drain electrode is shorter than a distance between the first p-type nitride semiconductor layer and the drain electrode.

7. The nitride semiconductor device according to claim 1,
wherein the nitride semiconductor device comprises the second p-type nitride semiconductor layer among the second p-type nitride semiconductor layer and the insulating layer,
the second p-type nitride semiconductor layer is further disposed in a position overlapping with the lateral surface of the first opening in the planar view of the substrate,
the second source electrode is further electrically connected to the second p-type nitride semiconductor layer, and
part of a lower surface of the second p-type nitride semiconductor layer is located in a position higher than an opening surface of the first opening.

8. The nitride semiconductor device according to claim 7,
wherein the lateral surface of the first opening is inclined relative to the bottom surface of the first opening,
an upper surface of the electron supply layer includes:
a flat portion along the bottom surface of the first opening;
an inclined portion along the lateral surface of the first opening; and
an outer edge portion extending from an upper end of the inclined portion in a direction away from the flat portion; and
the lower surface of the second p-type nitride semiconductor layer continuously covers at least part of the flat portion, the inclined portion, and part of the outer edge portion.

9. The nitride semiconductor device according to claim 7,
wherein in the planar view of the substrate, the second p-type nitride semiconductor layer overlaps with the first p-type nitride semiconductor layer.

10. The nitride semiconductor device according to claim 7 further comprising:
a third p-type nitride semiconductor layer disposed between the gate electrode and the electron supply layer to be spaced from the second p-type nitride semiconductor layer.

11. The nitride semiconductor device according to claim 7 further comprising:
an insulating film disposed between the gate electrode and the electron supply layer.

12. The nitride semiconductor device according to claim 7,
wherein the electron supply layer includes an impurity region disposed in a position overlapping with the gate electrode in the planar view of the substrate.

13. The nitride semiconductor device according to claim 7,
wherein a depressed portion is disposed in the electron supply layer in a position overlapping with the gate electrode in the planar view of the substrate.

14. The nitride semiconductor device according to claim 7,
wherein a distance between the second p-type nitride semiconductor layer and the drain electrode is shorter than a distance between the first p-type nitride semiconductor layer and the drain electrode.

15. The nitride semiconductor device according to claim 7,
wherein the second p-type nitride semiconductor layer includes a third opening that penetrates through the second p-type nitride semiconductor layer and reaches the electron supply layer, and
the second source electrode is in contact with the electron supply layer in a bottom surface of the third opening.
